(19) United States
(12) Patent Application Publication
(10) Pub. No.: US 2025/0266232 A1
(43) Pub. Date: Aug. 21, 2025

(54) CHARGED PARTICLE BEAM DISTORTION CORRECTION METHOD

(71) Applicant: DIRECT ELECTRON, LP, San Diego, CA (US)

(72) Inventor: Benjamin BAMMES, San Diego, CA (US)

(73) Assignee: DIRECT ELECTRON, LP, San Diego, CA (US)

(21) Appl. No.: 19/059,091

(22) Filed: Feb. 20, 2025

Related U.S. Application Data
(60) Provisional application No. 63/555,661, filed on Feb. 20, 2024.

(51) Int. Cl. H01J 37/147; H01J 37/06; H01J 37/244

(52) U.S. Cl. CPC H01J 37/1471; H01J 37/06; H01J 37/244; H01J 2237/1532; H01J 2237/1536; H01J 2237/22

(57) ABSTRACT

A charged particle beam device, method, and non-transitory computer-readable medium for scan distortion correction that includes receiving a beam desired ending position, receiving a beam starting position, calculating a director signal based on the beam starting position and the beam desired ending position, calculating a corrected signal based on the beam starting position, the director signal, a distortion model, and the beam desired ending position, and transmitting an instruction including the corrected signal to a beam director, where the corrected signal causes the beam director to move a beam of charged particles passing therethrough from the beam starting position to a beam corrected ending position.

### CROSS-REFERENCE TO RELATED APPLICATION(S)

The present application claims benefit under 35 U.S.C. § 119 (e) to U.S. Provisional Application No. 63/555,661, filed Feb. 20, 2024, which is incorporated by reference in its entirety.

### FIELD

The present disclosure relates to a method, apparatus, and system for correcting scan distortions in charged particle beams.

### BACKGROUND

Numerous technologies utilize beams of charged particles such as electrons, protons, and ions. Examples of such technologies include electron microscopy, including scanning electron microscopy (SEM), transmission electron microscopy (TEM), and scanning transmission electron microscopy; electron beam lithography (also known as e-beam lithography), electron beam melting (EBM), focused ion beam (FIB), and medical radiation treatment. These technologies are applied across a wide variety of fields and activities including scientific research in life sciences, materials sciences, geology, and other physical sciences; metrology, quality control, failure analysis, and research & development in the semiconductor, battery, catalyst, metallurgy, energy and other industries and other materials sciences; and pathology and other diagnostic/forensic imaging applications.

For example, lithography techniques such as e-beam lithography are used in manufacturing to create custom shapes on a surface by scanning a focused beam of electrons. This beam of electrons is typically used to selectively alter or remove an electron-sensitive film (resist) deposited on the surface. Focused ion beam (FIB) uses a focused beam of charged particles, typically other than electrons, for analysis, imaging, deposition, and/or ablation of materials.

Electron microscopy techniques such as scanning electron microscopy, transmission electron microscopy, and scanning transmission electron microscopy acquire images of specimens at high-resolution by scanning a focused electron beam over the specimen [Keyse, et al., 1998, “Introduction to Scanning Transmission Electron Microscopy”, Routledge. DOI: 10.1201/9780203749890].

In conventional two-dimensional (2D) STEM, one or more analog detectors—such as bright-field (BF) or high angle annular dark-field (HAADF) detectors—are used to record the total intensity within a certain range of scattering angles at each point on the specimen. In four-dimensional (4D) STEM, a pixelated detector is used to record an image of the electron scattering distribution at each point on the specimen, enabling a rich array of measurements, including the atomic resolution structure of specimens, local electric and magnetic fields, and strain [Ophus, 2019, “Four-dimensional scanning transmission electron microscopy (4D-STEM): From scanning nanodiffraction to ptychography and beyond”, Microscopy and Microanalysis, 25:563-582. DOI: 10.1017/S1431927619000497].

These structural measurements are used in a wide variety of applications including the development, characterization, and monitoring of catalysts, solar cell materials like perovskites, and advanced rechargeable batteries (ARBs). However, static equilibrium measurements of these materials are insufficient to understand and further develop the functioning of these materials. For example, real-time in situ observations of electrode materials during charge/discharge cycles have been useful for studying the complex nanoscale electrochemical reactions that result in battery degradation over time [Xie, et al., 2021, “A decade of advanced rechargeable batteries development guided by in situ transmission electron microscopy”, Nano Energy, 83:105780. DOI: 10.1016/j.nanoen.2021.105780].

The use of STEM for real-time measurement of dynamics (“in situ STEM”) is hindered by its relatively slow acquisition speed and specimen radiation damage concerns [Bárcena-González, et al., 2020, “CDrift: An algorithm to correct linear drift from a single high-resolution STEM image”, Microscopy and Microanalysis, 26:913-920. DOI: 10.1017/S1431927620001774; & Tyukalova and Duchamp, 2020, “Atomic resolution enabled STEM imaging of nanocrystals at cryogenic temperature”, Journal of Physics: Materials, 3:034006. DOI: 10.1088/2515-7639/ab8a95]. In both 2D and 4D STEM, the duration of acquisition for each pixel on the specimen is known as the dwell time. The total time to acquire a single image is the image size (total number of pixels) multiplied by the dwell time (plus any additional delays). For example, if extra delays are ignored and a 512×512 pixel area in each in situ movie frame is fully sampled, a hybrid pixel detector (such as EMPAD from Thermo Fisher Scientific) operating at 1100 frames per second (fps) delivers ˜4 minutes time-resolution for 4D STEM, which is far too slow for experiments examining dynamics. For perspective, solid-electrolyte interface (SEI) formation, which interferes with the battery function, completes within ˜20 seconds [Kushima, et al., 2017, “Liquid cell transmission electron microscopy observation of lithium metal growth and dissolution: Root growth, dead lithium and lithium flotsams”, Nano Energy, 32:271-279. DOI: 10.1016/j.nanoen.2016.12.001].

As cameras and scan generators get faster, in situ STEM is becoming feasible. For example, the KITE application-specific integrated circuit (ASIC) can output at >100,000 frames per second, delivering <10 microsecond dwell time [Zambon, et al., 2023, “KITE: High frame rate, high count rate pixelated electron counting ASIC for 4D STEM applications featuring high-Z sensor”, Nuclear Instruments and Methods in Physics Research Section A: Accelerators, Spectrometers, Detectors and Associated Equipment, 1048:167888. DOI: 10.1016/j.nima.2022.167888], corresponding to <2.7 second time resolution for in situ 4D STEM, sufficient for visualization of SEI formation. Monolithic active pixel sensors (MAPS) devices are also increasing dramatically in speed, including the Direct Electron Celeritas camera, capable of readout at >87,000 fps, delivering ˜11 microsecond dwell time [Levin, 2021, “Direct detectors and their applications in electron microscopy for materials science”, Journal of Physics: Materials, 4:042005. DOI: 10.1088/2515-7639/acOff9], corresponding to ˜3 second time resolution. Moreover, conventional 2D STEM can operate an order of magnitude faster. For example, a HAADF detector operating at 1 MHz delivers ˜0.3 s time resolution.

Unfortunately, however, improved detectors alone are insufficient to enable the full scope of in situ STEM. Decreasing the dwell time to increase time resolution introduces scan distortions, which hinder accurate interpretation of experimental results [Ortega, et al., 2021, “High temporal-resolution scanning transmission electron microscopy using sparse-serpentine scan pathways”, Scientific Reports, 11:22722. DOI: 10.1038/s41598-021-02052-1]. For conventional raster scans, where the beam proceeds across each row from left to right, then moves to the next row, proceeding again from left to right, these distortions are primarily evident at the beginning of each row, where the movement of the beam deviates significantly from its otherwise constant movement from left to right. Therefore, STEM acquisitions have often used “flyback time” to delay acquisition at the beginning of each row while the beam stabilizes. However, at high acquisition speeds (small dwell time), flyback time can become a significant bottleneck to time resolution [Mullarkey, et al., 2022, “Using your beam efficiently: Reducing electron dose in the STEM via flyback compensation”, Microscopy and Microanalysis, 28:1428-1436. DOI: 10.1017/S1431927621013908]. Additionally, flyback time is not applicable for methods to improve time resolution or reduce radiation damage by using unconventional scan patterns [Ortega, et al, 2021]. Scan distortions remain a considerable challenge to the use of scanning charged particle beam technologies such as high-speed 2D and 4D STEM for in situ studies of dynamic processes.

One approach to attempt to address these scan distortions is to use post-processing, such as applying linear interpolation to the acquired data after the fact to restore spatial accuracy. For example, Mullarkey, et al., used strontium titanate (SrTiO₃) and silicon (Si) to characterize flyback distortion. Horizontal deviations in the atomic spacing of acquired images were fit to a simple exponential distortion function using two parameters, A and b. These parameters were determined by least-squares minimization for a number of different dwell times and flyback times. STEM images were then corrected in post-processing through linear interpolation using the inverse of the distortion function. Similarly, Velazco, et al., (2020) calculated the positional deviation in atomic columns in strontium (Sr) from an SrTiO₃ specimen, using a variety of fully sampled scan patterns, including conventional raster, serpentine, and Hilbert scans. STEM images were corrected in post-processing through linear interpolation based on the measured deviations [Velazco A. et. al., 2022, “Reducing electron beam damage through alternative STEM scanning strategies, Part I: Experimental findings”, Ultramicroscopy, 232:113398. DOI: 10.1016/j.ultramic.2021.113398]. Ortega, et al., applied a similar strategy for serpentine scans with sparse-sampling [Ortega, et. al., 2021].

Roccapriore, et al., used principal component analysis to develop a Gaussian-process (GP) regression model for scan distortions, enabling reconstruction of undistorted images after data acquisition [Roccapriore, et al., 2021, “Identification and correction of temporal and spatial distortions in scanning transmission electron microscopy”, Ultramicroscopy, 229:113337. DOI: 10.1016/j.ultramic.2021.113337]. Ning, et al., also performed STEM distortion correction through post-processing, but also acquired pairs of images with different scan patterns. Because the image pairs were expected to be identical in the absence of scan distortions, the corresponding pixels in the image pairs were thought to be able to be aligned to correctly position each pixel and remove distortions [Ning, et. al., 2018, “Scanning distortion correction in STEM images”, Ultramicroscopy, 184:274-283. DOI: 10.1016/j.ultramic.2017.09.003]. A theoretical model of the direction and amplitude of distortions present in raster scans was applied to constrain the pixel alignments. Potapov & Lubk similarly performed distortion correction through post-processing using pairs of acquisitions with different scan patterns, but with the added complexity of fitting a cubic spline to the measured distortions to interpolate pixel positions for increased precision [Potapov & Lubk, 2021, “Correction for linear and non-linear distortions of STEM images”, Microscopy and Microanalysis, 27 (S1): 2320-2322. DOI: 10.1017/S1431927621008345].

Unfortunately, image correction through post-processing introduces several difficulties. First, stretching an image through linear interpolation may introduce artifacts in the image. Numerical simulations have revealed that interpolation can result in noticeable amplitude attenuation as well as phase errors that can generate false strain [Schreier, et al., 2000, “Systematic errors in digital image correlation caused by intensity interpolation”, Optical Engineering, 39:2915-2921. doi: 10.1117/1.1314593]. Second, correction of scan distortions in post-processing ignores the effect of the beam on the specimen. Low-dose STEM for beam-sensitive specimens requires a carefully controlled exposure, often <10 e-/Å2. Because scan distortions cause compression of the image, the exposure on the specimen in these compressed areas is greater than for the rest of the image. Radiation damage on the specimen is therefore variable across the field-of-view, reducing the reliability of the data. Efforts to reduce radiation damage through subsampling only exacerbate scan distortions due to the large and variable steps between scan points [Kovarik, et al., 2016, “Implementing an accurate and rapid sparse sampling approach for low-dose atomic resolution STEM imaging”, Applied Physics Letters, 109:164102. DOI: 10.1063/1.4965720; and Stevens, et al., 2018, “Subsampled STEM-ptychography”, Applied Physics Letters, 113:033104. DOI: 10.1063/1.5040496]. Finally, while linear interpolation may be straight-forward for density maps, its application to more complex 4D STEM measurements is unclear.

Furthermore, the use of post-processing for image correction is not a viable option for non-imaging techniques requiring a moving electron beam. No post-processing is even possible in applications such as electron beam melting (EBM) for metal additive manufacturing or electron beam lithography (EBL) for semiconductor manufacturing [Körner, 2016, “Additive manufacturing of metallic components by selective electron beam melting—a review”, International Materials Reviews, 61:361-377. DOI: 10.1080/09506608.2016.1176289; Nouri & Sola, 2020, “Electron beam melting in biomedical manufacturing” In: Wen C, editor, Metallic Biomaterials Processing and Medical Device Manufacturing, Woodhead Publishing. 271-314. DOI: 10.1016/B978-0-08-102965-7.00008-4; and Pease, 1981, “Electron beam lithography”, Contemporary Physics, 22:265-290, DOI: 10.1080/00107518108231531].

Accordingly, it is an objective of the present disclosure to provide methods and devices for correcting scan distortions in charged particle beams.

### SUMMARY

The present disclosure relates to a charged particle beam device, comprising a charged particle source configured to produce a beam of charged particles, a beam director configured to direct the beam of charged particles to a target, and processing circuitry configured to receive a beam desired ending position, receive a beam starting position, calculate a director signal based on the beam starting position and the beam desired ending position, calculate a corrected signal based on the beam starting position, the director signal, a distortion model, and the beam desired ending position, and transmit an instruction including the corrected signal to the beam director, wherein the corrected signal causes the beam director to move the beam of charged particles from the beam starting position to a beam corrected ending position.

The present disclosure also relates to a method of directing a beam of charged particles, the method comprising passing the beam of charged particles through a beam director, receiving a beam desired ending position, receiving a beam starting position, calculating a director signal based on the beam starting position and the beam desired ending position, calculating a corrected signal based on the beam starting position, the director signal, a distortion model, and the beam desired ending position, and transmitting an instruction including the corrected signal to the beam director, wherein the corrected signal causes the beam director to move the beam of charged particles from the beam starting position to a beam corrected ending position.

The present disclosure also relates to a non-transitory computer-readable medium having stored thereon, computer executable instructions, which when executed by a computer, cause the computer to execute operations, the operations comprising receiving a beam desired ending position, receiving a beam starting position, calculating a director signal based on the beam starting position and the beam desired ending position, calculating a corrected signal based on the beam starting position, the director signal, a distortion model, and the beam desired ending position, and transmitting an instruction including the corrected signal to a beam director, wherein the corrected signal causes the beam director to move a beam of charged particles passing therethrough from the beam starting position to a beam corrected ending position.

The present disclosure also relates to a charged particle beam device, comprising a charged particle source configured to produce a beam of charged particles; a beam director configured to direct the beam of charged particles to produce a directed beam; a beam corrector configured to provide a direction correction to the directed beam; and processing circuitry configured to receive a beam desired ending position, receive a beam starting position, calculate a director signal based on the beam starting position and the beam desired ending position, transmit a director instruction including the director signal to the beam director, calculate a corrector signal based on the beam starting position, the director signal, a distortion model, and the beam desired ending position, and transmit a corrector instruction including the corrector signal to the beam corrector, wherein the director signal causes the beam director to move the beam of charged particles, wherein the corrector signal causes the beam corrector to move the beam of charged particles, and wherein the beam director and beam corrector move the beam of charged particles from the beam starting position to a beam corrected ending position.

The present disclosure also relates to a method of directing a beam of charged particles, the method comprising passing the beam of charged particles through a beam director, receiving a beam desired ending position, receiving a beam starting position, calculating a director signal based on the beam starting position and the beam desired ending position, transmitting a director instruction including the director signal to a beam director, calculating a corrector signal based on the beam starting position, the director signal, a distortion model, and the beam desired ending position, and transmitting a corrector instruction including the corrector signal to a beam corrector, wherein the director signal causes the beam director to move the beam of charged particles, wherein the corrector signal causes the beam corrector to move the beam of charged particles, and wherein the beam director and beam corrector move the beam of charged particles from the beam starting position to a beam corrected ending position.

The present disclosure also relates to a non-transitory computer-readable medium having stored thereon, computer executable instructions, which when executed by a computer, cause the computer to execute operations, the operations comprising receiving a beam desired ending position, receiving a beam starting position, calculating a director signal based on the beam starting position and the beam desired ending position, transmitting a director instruction including the director signal to a beam director, calculating a corrector signal based on the beam starting position, the director signal, a distortion model, and the beam desired ending position, and transmitting a corrector instruction including the corrector signal to a beam corrector, wherein the director signal causes the beam director to move a beam of charged particles, wherein the corrector signal causes the beam corrector to move the beam of charged particles, and wherein the beam director and beam corrector move the beam of charged particles from the beam starting position to a beam corrected ending position.

The present disclosure also relates to a charged particle beam device, comprising a charged particle source configured to produce a beam of charged particles; a beam director configured to direct the beam of charged particles to produce a directed beam; a beam blanker; and processing circuitry configured to receive a beam desired ending position, receive a beam starting position, calculate a director signal based on the beam starting position and the beam desired ending position, calculate a beam movement parameter based on the director signal, the beam starting position, and the beam ending position, when the beam movement parameter is above a threshold movement value, transmit to the beam blanker a blank instruction including a blank signal that causes the beam blanker to prevent the beam from interacting with a target for a blank period, and transmit a director instruction including the director signal to the beam director, wherein the director signal causes the beam director to move the beam of charged particles from the beam starting position to the beam desired ending position.

The present disclosure also relates to a method of directing a beam of charged particles, the method comprising passing the beam of charged particles through a beam director; receiving a beam desired ending position; receiving a beam starting position; calculating a director signal based on the beam starting position and the beam desired ending position; calculating a beam movement parameter based on the director signal, the beam starting position, and the beam ending position; when the beam movement parameter is above a threshold movement value, transmitting to a beam blanker a blank instruction including a blank signal that causes the beam blanker to prevent the beam from interacting with a target for a blank period; and transmitting a director instruction including the director signal to the beam director, wherein the director signal causes the beam director to move the beam of charged particles from the beam starting position to the beam desired ending position.

The present disclosure also relates to a non-transitory computer-readable medium having stored thereon, computer executable instructions, which when executed by a computer, cause the computer to execute operations, the operations comprising receiving a beam desired ending position; receiving a beam starting position; calculating a director signal based on the beam starting position and the beam desired ending position; calculating a beam movement parameter based on the director signal, the beam starting position, and the beam ending position; when the beam movement parameter is above a threshold movement value, transmitting to a beam blanker a blank instruction including a blank signal that causes the beam blanker to prevent a beam of charged particles from interacting with a target for a blank period; and transmitting a director instruction including the director signal to a beam director through which the beam of charged particles is passing, wherein the director signal causes the beam director to move the beam of charged particles from the beam starting position to the beam desired ending position.

The present disclosure also relates to a charged particle beam device, comprising a charged particle source configured to produce a beam of charged particles; a beam director configured to direct the beam of charged particles to a target; and processing circuitry configured to receive a beam desired ending region, receive a beam starting position, calculate a director signal based on the beam starting position and the beam desired ending region, and transmit a director instruction including the director signal to the beam director, wherein the director signal causes the beam director to move the beam of charged particles from the beam starting position to a beam ending position within the beam desired ending region, and wherein the director instruction causes the beam director to scan the beam from the beam ending position to a second position in the beam desired ending region.

The present disclosure also relates to a method of directing a beam of charged particles, the method comprising receiving a beam desired ending region; receiving a beam starting position; calculating a director signal based on the beam starting position and the beam desired ending region; and transmitting a director instruction including the director signal to a beam director, wherein the director signal causes the beam director to move the beam of charged particles from the beam starting position to a beam ending position within the beam desired ending region, and wherein the director instruction causes the beam director to scan the beam from the beam ending position to a second position in the beam desired ending region.

The present disclosure also relates to a non-transitory computer-readable medium having stored thereon, computer executable instructions, which when executed by a computer, cause the computer to execute operations, the operations comprising receiving a beam desired ending region; receiving a beam starting position; calculating a director signal based on the beam starting position and the beam desired ending region; and transmitting a director instruction including the director signal to a beam director, wherein the director signal causes the beam director to move a beam of charged particles passing therethrough from the beam starting position to a beam ending position within the beam desired ending region, and wherein the director instruction causes the beam director to scan the beam from the beam ending position to a second position in the beam desired ending region.

### BRIEF DESCRIPTION OF THE DRAWINGS

FIGS. 1A-1F show exemplary STEM images exhibiting scan distortions using various scan patterns and dwell times, where FIG. 1A is for a raster scan with a dwell time of 100 μs, FIG. 1B is for a raster scan with a dwell time of 10 μs, FIG. 1C is for a serpentine scan with a dwell time of 100 μs, FIG. 1D is for a serpentine scan with a dwell time of 10 μs, FIG. 1E is for a rectangular spiral scan with a dwell time of 100 μs, FIG. 1F is for a rectangular spiral scan with a dwell time of 10 μs, and arrows show locations of distortion.

FIGS. 2A-2B show a model of a two-axis electromagnetic electron deflector that includes four deflector coils including two pairs of electromagnets, with each pair operated by application of a voltage denoted Vx and Vy to control the strength of the resulting magnetic field. Magnetic field lines are shown only for the y-axis deflectors.

FIG. 2B shows a zoomed in region of the center of the deflector shown in FIG. 2A where the electron beam passes. The arrow indicates the direction of deflection of the electron beam due to the magnetic field, in an orientation where the beam is going into the plane of the page.

FIG. 3 shows an example of an Amperian loop at the middle of a deflection coil where the magnetic field only has horizontal components along the loop shown.

FIGS. 4A-4D show simulated (FIGS. 4A and 4C) and observed (FIGS. 4B and 4D) scan distortions for HAADF STEM images of SrTiO₃ using a raster scan with a dwell time of 10 μs (FIGS. 4A and 4B) and 100 μs (FIGS. 4C and 4D).

FIGS. 5A-5D show simulated (FIGS. 5A and 5C) and observed (FIGS. 5B and 5D) scan distortions for HAADF STEM images of SrTiO₃ using a serpentine scan with a dwell time of 10 μs (FIGS. 5A and 5B) and 100 μs (FIGS. 5C and 5D).

FIGS. 6A-6D show simulated (FIGS. 6A and 6C) and observed (FIGS. 6B and 6D) scan distortions for HAADF STEM images of SrTiO₃ using a rectangular spiral scan with a dwell time of 10 μs (FIGS. 6A and 6B) and 100 μs (FIGS. 6C and 6D).

FIGS. 7A-7C show simulated HAADF STEM images of SrTiO₃ with 0.1 Å/pixel with 64×64 pixels and a dwell time of 10 μs (FIG. 7A), 100 μs (FIG. 7B), 1000 μs (FIG. 7C).

FIG. 7D shows a plot of the x coordinate for 12 scan points near the middle of the 10 μs dwell time simulation including the desired x coordinate on the specimen (solid line) and the actual x coordinate of the beam due to the behavior of the scan coils (dashed line).

FIGS. 8A-8D show 2D STEM HAADF images of a line-grating calibration specimen, acquired with a 2.625 μs dwell time using a serpentine scan pattern, where FIG. 8A shows the uncorrected image and FIG. 8B showing a Fourier transform of the uncorrected image while FIG. 8C shows the corrected image and FIG. 8D showing a Fourier transform of the corrected image.

FIGS. 9A-9D show 2D STEM HAADF images of a line-grating calibration specimen, acquired with a 2.625 μs dwell time using a rectangular scan pattern, where FIG. 9A shows the uncorrected image and FIG. 9B showing a Fourier transform of the uncorrected image while FIG. 9C shows the corrected image and FIG. 9D showing a Fourier transform of the corrected image.

FIGS. 10A-10D show visualizations of the patterns tested, with the dark are denoting the beginning of the scan and the light area denoting the end of the scan where FIG. 10A is a conventional raster scan pattern, FIG. 10B is a serpentine scan pattern, FIG. 10C is a rectangular spiral scan pattern, and FIG. 10D is a random scan pattern.

FIGS. 11A-11D show images obtained with a conventional raster scan pattern (FIGS. 11A and 11C) and a difference map calculated from theoretically perfect scan coils with no distortions (FIGS. 11B and 11C). Both uncorrected (FIGS. 11A and 11B) and corrected (FIGS. 11C and 11D) are shown. In the difference maps, black pixels in the difference maps indicate no difference between the obtained image and the theoretically perfect scan.

FIGS. 12A-12D show images obtained with a serpentine scan pattern (FIGS. 12A and 12C) and a difference map calculated from theoretically perfect scan coils with no distortions (FIGS. 12B and 12C). Both uncorrected (FIGS. 12A and 12B) and corrected (FIGS. 12C and 12D) are shown. In the difference maps, black pixels in the difference maps indicate no difference between the obtained image and the theoretically perfect scan.

FIGS. 13A-13D show images obtained with a rectangular spiral scan pattern (FIGS. 13A and 13C) and a difference map calculated from theoretically perfect scan coils with no distortions (FIGS. 13B and 13C). Both uncorrected (FIGS. 13A and 13B) and corrected (FIGS. 13C and 13D) are shown. In the difference maps, black pixels in the difference maps indicate no difference between the obtained image and the theoretically perfect scan.

FIGS. 14A-14D show images obtained with a random scan pattern (FIGS. 14A and 14C) and a difference map calculated from theoretically perfect scan coils with no distortions (FIGS. 14B and 14C). Both uncorrected (FIGS. 14A and 14B) and corrected (FIGS. 14C and 14D) are shown. In the difference maps, black pixels in the difference maps indicate no difference between the obtained image and the theoretically perfect scan.

FIGS. 15A-15E show images demonstrating the improvement in quality using a “distributed random” scan pattern (FIG. 15A) from uncorrected (FIG. 15B), after distortion correction (FIG. 15C), after use of the calculated position of each scan point by applying inpainting to specimen pixels that were not sampled (FIG. 15D) compared to a theoretically perfect scan (FIG. 15E).

FIG. 16 shows a depiction of a supervised machine learning system for electromagnetic coil distortion correction that uses simulated data is used to train a regression model, has calibration parameters and the desired pattern of electron beam movement input to the regression model, and outputs the optimal voltage(s) to apply to the coils.

FIG. 17 shows a depiction of the correction of an electromagnetic coil beam distortion using electrostatic beam deflectors

FIG. 18 shows a schematic of a hardware system for performing a method, according to an exemplary embodiment of the present disclosure.

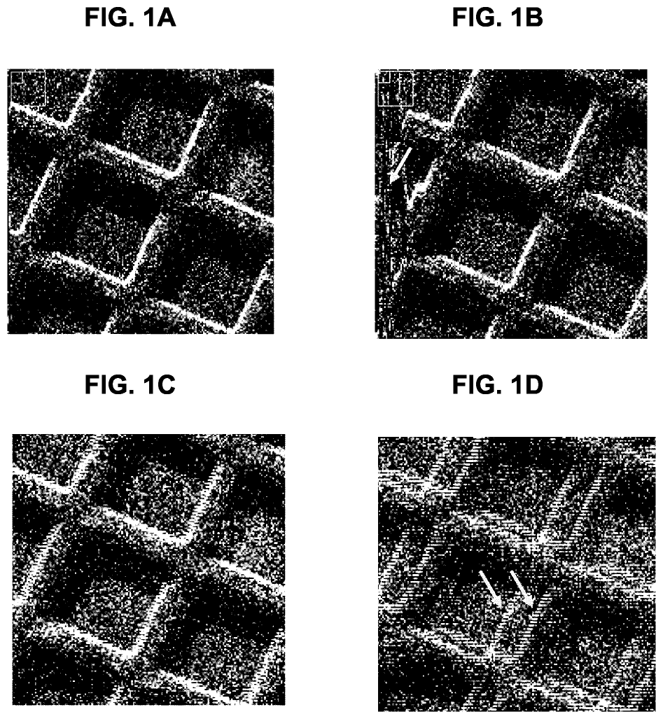

### DETAILED DESCRIPTION

In the following description, it is understood that other embodiments may be utilized and structural and operational changes may be made without departure from the scope of the present embodiments disclosed herein.

As used herein the words “a” and “an” and the like carry the meaning of “one or more.” The term “plurality”, as used herein, is defined as two or more than two. The term “another”, as used herein, is defined as at least a second or more.

The terms “including” and/or “having”, as used herein, are defined as comprising (i.e., open language). Reference throughout this disclosure to “one embodiment”, “certain embodiments”, “an embodiment”, “an implementation”, “an example”, or similar terms means that a particular feature, structure, or characteristic described in connection with the embodiment is included in at least one embodiment of the present disclosure. Thus, the appearances of such phrases or in various places throughout this disclosure are not necessarily all referring to the same embodiment. Furthermore, the particular features, structures, or characteristics may be combined in any suitable manner in one or more embodiments without limitation.

The present disclosure relates to a charged particle beam device (“device”). The present disclosure also relates to a method of directing a beam of charged particles. In some embodiments, the device is configured to perform the method of directing a beam of charged particles. In some embodiments, the method of directing a beam of charged particles involves scan distortion correction.

In some embodiments, the charged particle beam device includes a charged particle source configured to produce a beam of charged particles. In general, the charged particles can be any type of charged particle known to one of ordinary skill in the art. Examples of suitable charged particles include, but are not limited to electrons, protons, helium nuclei, ions of an element such as gallium, helium, argon, xenon, carbon, nitrogen, oxygen, silicon, chromium, iron, cobalt, nickel, germanium, indium, tin, gold, and lead, and combinations of these. Electron beams, also called e-beams, may be useful in various electron microscopy techniques, such as scanning electron microscopy (SEM), transmission electron microscopy (TEM), and scanning transmission electron microscopy (STEM); electron beam lithography; elemental analysis techniques such as microprobe analysis and energy-dispersive X-ray spectroscopy; and the like. Ions of various chemical elements may be useful in ion milling; focused ion beam (FIB) manufacturing; sputtering; etching; deposition; and the like. In some embodiments, the charged particles are electrons.

In general, the charged particle source can be any suitable source known to one of ordinary skill in the art. For example, for electrons, typical electron beam sources include field emission guns (FEG) and thermionic electron sources.

Field Emission Guns (also called Field-Effect Guns or Field-effect emitters) use a high-strength electric field to reduce the work function of a heated electron emitter. Typically, FEGs include a tip formed from small bent or looped pieces of metal. A common FEG tip is a “tungsten hairpin”.

Thermionic sources use high-temperature to facilitate electron emission. Thermionic sources typically contain a tip made from crystalline (typically single-crystal) electron emissive material. The most common electron emissive material used in thermionic sources is Lanthanum hexaboride (LaB₆), but cerium hexaboride (CeB₆) and mixed lanthanum cerium hexaboride ((La,Ce)B₆) are also frequently used. The crystal(s) typically have a (100) orientation, since the (100) crystalline plane provides 4-fold symmetry and exhibits the lowest work function. The electron emissive material is mounted at the tip of a heater, typically a carbon rod connected at the tip and split into to “legs” at an opposite end. The legs are connected to a voltage source and current can flow up one leg, through the connected tip near the electron emissive material, then down the other leg. This current causes resistive heating including of the tip of the heater. The heat is transferred to the electron emissive material, facilitating thermionic emission. A high-quality thermionic emitter, such as a LaB₆ emitter, exhibits a high brightness (current density), a low energy spread of emitted electrons (leading to, for example, a higher imaging resolution), a low evaporation rate (leading to long usage lifetime), a lower work function (leading to a lower operating temperature and longer service life), and a stable emission.

In some embodiments, the charged particle beam device can include various components that facilitate the formation of a beam from the charged particles emitted by or produced by the charged particle source. For example, the charged particle beam device can include a collimator, an aperture, an electrode (also called an accelerator), and combinations of these.

In some embodiments, the charged particle beam device includes a beam director. The beam director can be configured to position a beam of charged particles. In some embodiments, the beam director is an electromagnetic deflector. An electromagnetic deflector uses a generated magnetic field to direct or steer the beam of charged particles. Typically, an electromagnetic deflector includes one or more electromagnets to direct the beam of charged particles along a single axis. The electromagnets are frequently in the form of wire coils. In the context of electromagnetic deflectors, the terms “electromagnet” and “coil” are frequently used interchangeably. A typical design for an electromagnetic beam director can include a pair of coils per axis, though other numbers of coils per axis may be used as well such as 1, 2, 3, 4, 5, 6, 7, 8, 9, 10, or more. In general, the charged particle beam device of the present disclosure can include any number of electromagnets or pairs of electromagnets. In some embodiments, the charged particle beam device of the present disclosure includes a two-axis electromagnetic deflector. A two-axis electromagnetic deflector is capable of directing the beam of charged particles along two axes, typically perpendicular to each other, to direct the beam within a 2D plane. In some embodiments, the two-axis electromagnetic deflector can include four electromagnets (coils). In some embodiments, the four electromagnets (coils) can be arranged into two pairs, a first pair for the x-axis (or horizontal direction or left-right direction) and a second pair for the y-axis (or vertical direction or front-back direction). In some embodiments the beam director may be configured to control the charged particle beam along one axis, two axes, three axes, four axes, six axes, eight axes, or some other number of axes. In general, these axes may be oriented in any suitable directions relative to each other. For example, the two axes may be perpendicular (or approximately perpendicular) to each other. As an example, the three axes may be mutually perpendicular (or approximately perpendicular) in 3D space or be oriented in the same plane, such as at angles of approximately 60°. As an example, six axes (also known as hexapole) may be oriented in the same plane, such as at angles of approximately 30°. In some embodiments, each axis of deflection may involve combinations of one or more electromagnetic coils and/or one or more electrostatic deflectors as described below.

In some embodiments, the charged particle beam device includes suitable hardware for controlling various aspects of the charged particle beam. Such aspects can include a beam shape, beam coherence, beam divergence, astigmatism, and the like. For example, the charged particle beam device can include a magnetic lens. A magnetic lens may be useful for forming charged particles generated by a suitable charged particle source into a beam, focusing the beam, diverging (spreading) the beam, and the like. As an example, the charged particle beam device can include a stigmator. A stigmator is that reduces astigmatism of the beam. Typically, a stigmator imposes an electric and/or magnetic field having an appreciable quadrupole moment or component on to the beam.

In general, such suitable hardware for controlling various aspects of the charged particle beam can be placed at any point along a beam path. For example, one or more such hardware components can be placed before the beam director. Alternatively or in addition, one or more such hardware components can be placed after the beam director. Similarly, various such hardware components can be placed before and/or after a beam corrector described below. It should be understood that such hardware components may be sources of scan distortion.

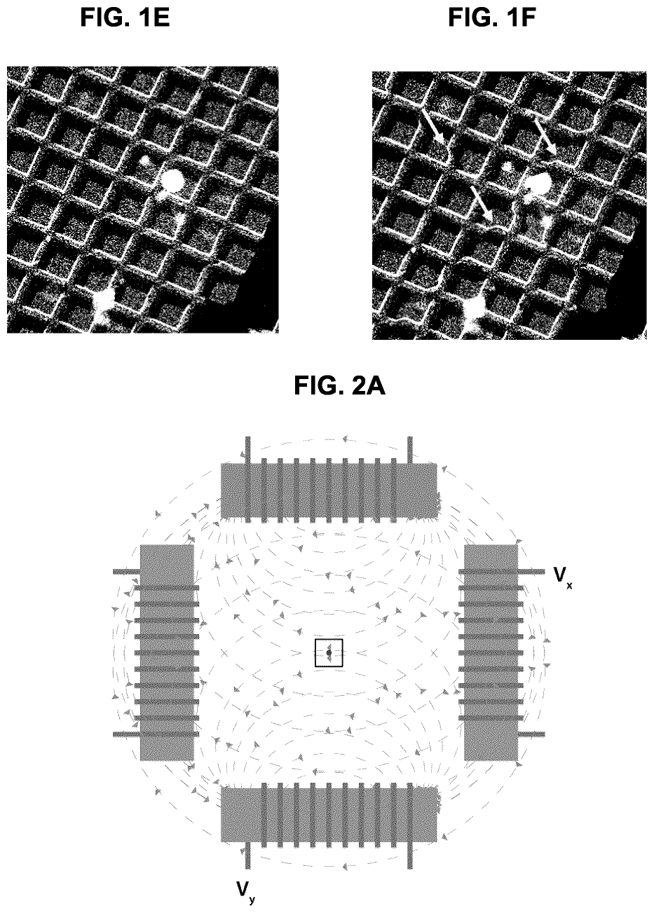

FIG. 2A shows an exemplary two-axis deflector. This exemplary deflector includes two pairs of electromagnets, with each pair operated by application of a voltage (denoted by Vx and Vy, with respect to ground) to control the strength of the resulting magnetic field. The applied voltages may be supplied by electronic circuits containing components and designs. For example, a pre-emphasis filter, improved amplifiers, or field programmable gate arrays (FPGAs) can be included in the control circuitry to reduce the settling time for voltages output to the deflectors [Lee & Thong, 1999, “Improving the speed of scanning electron microscope deflection systems”, Measurement Science and Technology, 10:1070. DOI: 10.1088/0957-0233/10/11/316; Carla, et al., 2004, “Development of an ultralow current amplifier for scanning tunneling microscopy”, Review of Scientific Instruments, 75:497-501. DOI: 10.1063/1.1641159; and Gregorat, et al., 2024, “Design of an FPGA-Based Controller for Fast Scanning Probe Microscopy”, Sensors 24:6108. DOI: 10.3390/s24186108]. Such components and designs may be specifically designed to, for example, reduce scan distortions, increase voltage reliability, reduce magnetic field variability, or maximize speed. In the figure, magnetic field lines are shown only for the y-axis deflectors. FIG. 2B shows a zoomed in region (denoted by the square in the center of FIG. 2A), of the center of the deflector where the electron beam passes. The arrow indicates the direction of deflection of the electron beam due to the magnetic field, assuming that the beam is going into the plane of the page.

In some embodiments, the charged particle beam device includes processing circuitry. In some embodiments, the processing circuitry is configured to control various aspects of the charged particle beam device. In some embodiments, the processing circuitry is conjured to perform a method of correcting a scan distortion described below. In some embodiments, the processing circuitry is further configured to control various aspects of the operation of the device (e.g., perform actions related to generation and/or general control of the charged particle beam, actions related to imaging, etc.). In some embodiments, the device includes separate processing circuitry to control the operation of the device and to perform the method of correcting a scan distortion.

Distortions in electromagnetic beam deflectors originate from several sources. A first source of scan distortion is propagation delay in the scan controller and current amplifier, as well as impedance (RC delay) in the electronic circuits and electromagnetic coil [Lee, et al., 1999, “Improving the speed of scanning electron microscope deflection systems”, Measurement Science and Technology, 10:1070. DOI: 10.1088/0957-0233/10/11/316]. These sources can introduce transient (time-dependent) distortions. For electromagnetic deflectors, these electronic delays may be combined with or complicated by linear errors in the magnetic field introduced by eddy currents [Parks, 2020, “Modelling of electron beam deflection system for beam position control in metal additive manufacturing”, Dissertation, The University of British Columbia, Vancouver, Canada]. These are electrical currents induced by a changing magnetic field, as predicted by Faraday's law of induction. These currents generate their own magnetic field, which oppose the initial magnetic field that generated the currents. Therefore, eddy currents typically act to delay and attenuate changes in the magnetic field of an electromagnetic deflector. The overall time-dependent response is typically used as the motivation for “flyback time” in conventional raster scan patterns for electron beam applications such as STEM.

A second source of scan distortions is ferromagnetic hysteresis, which causes inaccuracy in the generated magnetic field for a given input voltage, the magnitude of which depends on the previous state of the deflector [van Bree, 2011, “Control of dynamics and hysteresis in electromagnetic lenses”, Dissertation, Technische Universiteit Eindhoven, Eindhoven, Netherlands, DOI: 10.6100/IR711031]. This tends to introduce steady-state (time-invariant) distortions. There is also some evidence that some hysteresis effects are also rate-dependent, which would contribute to the time-dependent response discussed above [Ikhouane, 2020, “Theory of continuous rate-dependent hysteresis”, Communications in Nonlinear Science and Numerical Simulation, 80:104970. DOI: 10.1016/j.cnsns.2019.104970]. Hysteresis is a nonlinear effect, depending not only on the input but also on the previous state. Therefore, hysteresis distortions in STEM images will depend on the spatial coordinates in the image (the input) and the scan pattern (which dictates the previous position). Hysteresis is generally repeatable, so that it can either be mapped/corrected or reduced by maintaining consistent input trajectories.

A third source of scan distortion is crosstalk between the x and y beam deflectors. This crosstalk may introduce inaccuracies in the beam position dependent on the combination of the x and y magnetic fields [Parks, 2020, “Modelling of electron beam deflection system for beam position control in metal additive manufacturing”, Dissertation, The University of British Columbia, Vancouver, Canada].

The present disclosure relates to a method of correcting scan distortions.

In some embodiments, the method involves calculating a director signal based on a beam starting position and a beam desired ending position. The director signal can be calculated as a signal provided to a beam director (such as the electromagnetic director described below) to move the beam from the beam starting position to the beam desired ending position. The director signal can be transmitted to the beam director. In some embodiments, the director signal can be included in a director instruction. The director instruction can include any number of director signals and any other suitable information necessary or helpful for the director do direct the beam. In some embodiments, the director instruction includes a plurality of director signals. Each director signal may correspond to a single beam desired ending position or beam movement. In some embodiments, the director instruction can include some information or data related to how the director is to handle the plurality of director signals. For example, the director instruction can include a sequence for the director signals, a timing of the director signals, or some other suitable information.

In some embodiments, prior to this calculation, the method includes receiving the beam desired ending position. In general, the beam desired ending position can be received from any suitable source. For example, the beam desired ending position can be received from a user input, received via transmission from another device, and/or retrieved from a stored location such as a memory location or a database.

In some embodiments, the method includes determining a beam starting position. In general, the beam starting position can be determined using any suitable method and with any suitable hardware known to one of ordinary skill in the art. For example, the beam starting position can be determined using a beam position detector and/or retrieved from a stored location such as a memory location or a database, such as a position history described below. In general, a beam position detector can be any suitable device or apparatus capable of detecting or measuring a position of the beam.

In some embodiments, the method involves using the calculated director signal, the beam desired ending position, and a distortion model to calculate a beam uncorrected ending position. In some embodiments, the beam uncorrected ending position is not the same as the beam desired ending position. A difference between the beam uncorrected ending position and the beam desired ending position can be referred to as beam position error, overshoot, undershoot, or some other similar term.

In some embodiments, the method involves using the beam starting position, the director signal, a distortion model, and the beam desired ending position to calculate a correction signal. In some embodiments, the calculation of the correction signal further uses the distortion model. Such a calculation can be referred to as a “correction calculation” or other similar term. In some embodiments, the method involves using the beam starting position, the director signal, a distortion model, the beam desired ending position, and the beam uncorrected ending position to calculate a correction signal.

In some embodiments, the correction signal can be provided to a suitable beam deflector. In general, the beam deflector can be an electromagnetic deflector, an electrostatic deflector, some other deflector, or a combination of these. In some embodiments, the correction signal can be provided to the beam director. That is, the correction signal and the director signal are provided to the same electromagnetic components. As used herein, “correction signal” refers to a signal that can be provided to a suitable piece of hardware configured to control the beam of charged particles, such as a beam director, a separate electromagnetic beam corrector, or an electrostatic deflector as described below, that causes the hardware to move the beam from the beam uncorrected ending position to a beam corrected ending position. In some embodiments, correction signal can be used to cause the beam director to move the beam from the beam uncorrected ending position to a beam corrected ending position.

In some embodiments, the correction signal can be provided to an electromagnetic deflector that is not the beam director. For example, the device may include a beam director and a separate “electromagnetic beam corrector”. In general, the separate electromagnetic beam corrector can be similar to the beam director as described above. A separate electromagnetic beam corrector can be integrated into the device in any suitable location. For example, the separate electromagnetic beam corrector can be position along the beamline downstream of the beam director.

In some embodiments, the device includes a beam corrector that is not an electromagnetic deflector. In some embodiments, the device includes an electrostatic beam deflector (also referred to as an electrostatic corrector in the context of the present disclosure). An electrostatic deflector is capable of directing a beam of charged particles by creating an electric field, in contrast to the electromagnetic deflector which uses a magnetic field as described above. Typically, electrostatic deflectors include a pair of parallel plates configured to generate an electric field therebetween. The beam may pass between the parallel plates and be deflected by the generated electric field. In general, the device of the present disclosure can include any number of electrostatic deflectors or pairs of electrostatic deflectors. In some embodiments, the charged particle beam device of the present disclosure includes a two-axis electrostatic deflector. A two-axis electrostatic deflector is capable of directing the beam of charged particles along two axes, typically perpendicular to each other, to direct the beam within a 2D plane. In some embodiments, the two-axis electromagnetic deflector can include four plates. In some embodiments, the four plates can be arranged into two pairs, a first pair for the x-axis (or horizontal direction or left-right direction) and a second pair for the y-axis (or vertical direction or front-back direction).

The electrostatic beam corrector can be integrated into the device in any suitable location. For example, the electrostatic beam corrector can be position along the beamline downstream of the beam director.

The use of an electrostatic beam corrector may be advantageous because electrostatic deflectors typically have much more rapid response times compared to electromagnetic deflectors. This much faster response time can allow the magnitude of the correction to change during the dwell time of the beam at each desired position, keeping the beam position stable during the dwell time. This much faster response time can also allow for rapid application of the correction, which may be advantageous in real-time applications as described below. The dwell time refers to an amount of time the charged particle beam remains in a target area, such as an area corresponding to a single pixel, during a scan. A longer dwell time may be advantageous for allowing more charged particles to interact with the target area of the sample or specimen. This higher number of charged particles may be associated with a stronger or more easily detected signal and/or a higher quality image. However, the higher number of charged particles may also be associated with increased sample damage. Dwell time is typically used as a metric or index to describe a scan speed of the charged particle beam.

Typically, electrostatic deflectors require significantly more power than electromagnetic coils to cover the same range of electron beam deflection. These power requirements may limit the practicality of completely replacing electromagnetic coils with electrostatic deflectors. However, using an electrostatic deflector to apply a relatively minor correction to a beam position after an electromagnetic deflector may be particularly advantageous. For example, if an electrostatic deflector were paired with electromagnetic coils, the electrostatic deflector could simply perturb the position of the electron beam to correct the distortions introduced by the electromagnetic coils. Because of the high speed of electrostatic deflectors, these perturbations could be applied faster than the dwell time for the desired movement of the electron beam, so that the electrostatic deflector prevents motion of the beam within the dwell time.

A correction signal that is provided to a separate electromagnetic beam corrector or an electrostatic deflector may be referred to as a “corrector signal” or other similar term. Conceptually, the corrector signal can be calculated similarly for electrostatic and electromagnetic deflectors with practical differences based on differences between the two types and the hardware used to implement them.

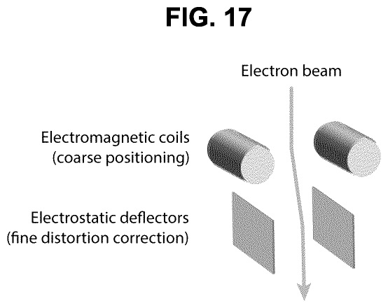

FIG. 17 shows a depiction of the correction of an electromagnetic coil beam distortion using electrostatic beam deflectors.

The correction signal or corrector signal can be transmitted to the apparatus or hardware suitable for performing the correction. For example, when the beam director is configured to receive the correction signal and perform the beam correction, the correction signal can be transmitted to the beam director. When the beam corrector is configured to perform the beam correction the correction signal (corrector signal) can be transmitted to the beam corrector. In some embodiments, the correction signal can be included in a correction instruction (corrector instruction). The correction instruction can include any number of correction signals and any other suitable information necessary or helpful for the director and/or corrector do direct the beam. In some embodiments, the correction instruction includes a plurality of correction signals. Each correction signal may correspond to a single beam desired ending position or beam movement. In some embodiments, the correction instruction can include some information or data related to how the director and/or corrector is to handle the plurality of correction signals. For example, the correction instruction can include a sequence for the correction signals, a timing of the correction signals, or some other suitable information.

In some embodiments, the beam corrected ending position is closer to the beam desired ending position compared to the beam uncorrected ending position. In some embodiments, the beam corrected ending position is the beam desired ending position.

In some embodiments, the calculation uses the model of scan coil behavior described below to calculate the actual coordinate position of the electron beam from the director signal (e.g., voltages) that are sent and/or will be sent to the electromagnetic coils (e.g., an uncorrected beam position. For example, in some embodiments, for each desired scan point, the input voltages for the x and y scan coils are estimated assuming no distortions (director signal). Then, a theoretical model (distortion model) is used to calculate the actual resulting position of the beam (uncorrected beam position). In some embodiments, a deviation between the desired and actual beam position can be calculated, and the x and y voltages can be adjusted to move the beam closer to the target position. In some embodiments, this process can be repeated iteratively until the calculated actual position of the beam is within a pre-determined margin-of-error of the target position.

In some embodiments the calculation uses a history of previous voltages that already have been sent to the electromagnetic coils. This history may be referred to as a beam history. In some embodiments, this calculation can be performed using a beam history. The beam history can include previous beam position(s) and/or previous director signal(s)/correction signal(s). In general, the beam history can be in any suitable format, such as a table, array, database, or the like. The beam history can be stored in a suitable memory location accessible by the processing circuitry of a suitable charged particle beam device.

In some embodiments, the method includes the use of suitable hardware that can output arbitrary voltage values to the director (e.g., electromagnetic coils). In some embodiments, the device includes suitable hardware that can output arbitrary voltage values to the director. Such hardware may include programmable high speed digital to analog converters that convert input codes to voltage signals used to control the director. For example, the hardware can include a DE-FreeScan scan generator available from Direct Electron. Scan generators that use voltage ramps, such as those associated with raster scans, may be unsuitable. Such voltage ramps may not permit the director to output the necessary electromagnetic output to achieve the distortion correction.

In some embodiments, the calculation of the correction signal can be performed iteratively. Iteration may be advantageous to bring the beam corrected ending position closer to the beam desired ending position. For example, the method can involve a calculation of a distance or error between the beam corrected ending position and the beam desired ending position. If this distance or error is above a certain threshold, another correction calculation can be performed. In this other correction calculation, the first calculated beam corrected ending position and first calculated correction signal can be used as the basis for the subsequent correction calculation. That is, instead of an uncorrected beam ending position, the first corrected beam ending position can be used as an input. Similarly, the first correction signal can be used as an input instead of the director signal. In general, any number of iterations of such correction calculations can be performed.

In some embodiments, the scan distortion correction method can be performed in real-time. That is, the scan distortion correction method can be performed while the charged particle beam is active and/or interacting with a target or substrate. The calculation of a correction signal can be performed upon receiving a beam desired ending position. For example, the charged particle beam can be moved to a location. This location can serve as the beam starting position. The device can receive a new beam desired ending position, such as by a user input or from a suitable memory location (e.g., reading a pre-programmed scan pattern), and then perform the correction calculation. In some embodiments, the correction calculation is performed before the beam begins moving. In some embodiments, the director signal is not transmitted to the beam director. In such an embodiment, only the correction signal can be transmitted. This way, the beam only begins moving based on the correction signal and moves to the corrected beam ending position. In some embodiments, the director signal is transmitted to the beam director. Such transmission can be performed before transmitting the correction signal. This may cause the director to begin moving the beam to the uncorrected beam ending position. Then, the correction signal can be transmitted, which causes the beam director to move the beam to the corrected beam ending position. In such an embodiment, the beam may or may not ever actually reach the uncorrected beam ending position.

The use of real-time calculation of the correction signal may be useful in situations where direct user input is required. For example, in microscopy, it is very advantageous to allow the user to directly control the size and location of the area imaged. The user may wish to change some parameter of the area imaged such as location, zoom level, or the like. Because of this, the beam must be capable of responding to essentially any suitable user input, often without prior notification. Real-time calculation of the correction signal can afford the type of responsiveness required for real-time user control of the beam.

In some embodiments, the scan distortion correction method can include calculation of a plurality of correction signals, each corresponding to a pre-selected or pre-set beam desired ending position. The plurality of pre-selected beam desired ending positions can be organized, for example, as an ordered list, ordered array, or some other ordering that can convey a particular order of positions. Such an order can allow the ending position of an entry (e.g., a certain beam desired ending position or beam corrected ending position) to serve as a beam starting position for an immediately following entry. This may allow for pre-planning or pre-programming of an entire scan. For example, a scan can be provided as a series of beam desired ending positions (and/or a series of specific beam movements). Based on the series of beam desired ending positions, a series of director signals and correction signals can be calculated. Such calculation can be performed prior to initiating any beam movement or even initiating the generation of the beam. The entire series of correction signals (and optionally the series of director signals) can be transmitted to the beam director to direct the beam to perform the pre-planned scan.

Pre-planning a scan may be particularly useful in applications such as lithography, particularly e-beam lithography, or ion milling (FIB milling). In such applications or techniques, direct user control or on-the-fly changes to the beam position are not typically required. Further, it may be advantageous to pre-plan a scan pattern or series of beam movements/positions for repeated use. For example, a certain e-beam lithography scan may be prepared to fabricate a particular chip. Pre-calculating the correction signal can allow the corrected scan to be performed any number of times to repeatedly fabricate the particular chip.

In some embodiments, one or more of the calculations described above can be performed using a machine learning (ML) model. In general, the ML model can perform any function or series of functions associated with the calculation of the director signal, the beam uncorrected ending position, the correction signal, a calculated or expected beam corrected ending position (e.g., a beam ending position calculated using the correction signal, optionally with the director signal as well), some other parameter, or combinations of these.

In general, the ML model may be any suitable type of ML model. Examples of types of ML models include linear regression models, logistic regression models, support vector regression models, random forest models, boosted tree models, multi-layer perceptron models, neural network models such as an artificial neural network (ANN), a recurrent neural network (RNN), and a convolutional neural network (CNN), a fuzzy logic model, and the like.

In general, a ML model may be trained before it is used to make an inference from new input data. Training a machine learning model may involve, for example, determining parameters of the ML model, such as values of weights associated with one or more nodes of a neural network model. In some embodiments, a ML model may be trained in a supervised manner using a training data set that includes labeled training data. The labeled training data may include inputs and corresponding annotated outputs that the ML model is to approximate using learned weight values. For example, the labeled training data can include various simulated scans which may include specific beam desired ending positions, beam actual ending positions, director signals, distances/errors between the beam desired ending positions and the beam actual ending position, and the like. In some other embodiments, a ML model may be trained in an unsupervised manner in which parameters of the ML model may be determined without using labeled training data.

In some embodiments, the parameter(s) of a ML model may be trained via loss minimization by feeding a training dataset to the ML model. For example, training a ML model may include optimization of parameters (e.g., weights or biases) of the ML model using techniques such as gradient descent and backpropagation techniques. A validation dataset may also be allocated (e.g., about 20%) from the training dataset to validate a trained ML model before deploying the ML model.

In some embodiments, the ML model can include a classifier. As used herein, a “classifier” may refer to a type of ML model that is trained to categorize inputs into one or more classes of a set of classes. Inputting data into a trained classifier may result in an output that categorizes the input data into an input that affects a particular type of distortion or one that does not affect the particular type of distortion or an input that requires a specific type of distortion correction or one that does not require the specific type of distortion correction. Thus, a properly trained classifier may provide an estimation of a mapping between input variables and discrete (as opposed to continuous) output variables. A classifier may be trained, for example, through a supervised fashion (including optimization and backpropagation), where the training data may comprise known and labeled information. In some cases, the trained classifier may use a regression technique such as logistic regression, which uses a logistic function to model a variable that may have multiple possible discrete outcomes, e.g., a binary or dichotomous outcome such as “expected distance between calculated or expected beam ending position and desired ending position is below a threshold” or “expected distance between calculated or expected beam ending position and desired ending position is above a threshold.” Logistic regression can map the predicted values to probabilities using, for example, a sigmoid function. A sigmoid function can map values between one end to another (e.g., 0 to 1), where one end may correspond to a value such as a movement parameter being above a threshold and the other end may correspond to the movement parameter being below the threshold. In some implementations, one or more threshold values may be needed for the classifier to map the input data to one of the discrete outcomes. For example, if the probability is determined to be above a 0.2 threshold needed to be classified as a “0” but below a 0.8 threshold needed to be classified as a “1,” then the ML model may consider the determination invalid or null rather than one of the binary outcomes.

In some embodiments, the ML model can include a regression model (“regressor”). As used herein, a “regression model” may refer to a type of ML model that is trained to predict the value of an output variable based on one or more inputs. In general, the output variable may take on various values, including discrete or continuous values. In general, a regression model can use some mathematical function or relationship to predict the output variable given the input(s). Typically, a regression model determines the parameters of the mathematical function or relationship automatically during training. In the context of the present disclosure, the regression model may be particularly useful for calculating the director signal, the beam uncorrected ending position, the correction signal, a calculated or expected beam corrected ending position (e.g., a beam ending position calculated using the correction signal, optionally with the director signal as well), or combinations of these. In some embodiments, these calculations may yield continuous outputs. For example, the correction signal and/or director signal make take the form of an arbitrary voltage (e.g., any value from ˜−10V to ˜+10V) that can be provided to an electromagnetic deflector as described above.

In some embodiments, the ML model can be trained on training data that include various calibration parameters. Examples of these calibration parameters include the parameters A, B, C, and/or T discussed in the Examples below. For example, the ML model could be trained using a process that involves applying Equation 33 (described below), Equation 39 (described below), or a variant thereof, to each scan point. After training, the ML model would take as inputs the device's calibration parameters (e.g., A, B, C, and/or T described in the Examples section below), the coordinates of the desired position of the beam, a list of the recent history of the electromagnetic coils' voltages (voltage versus time, for each coil present), and the like. The output of the ML model could include the voltages to send to the electromagnetic coils to achieve the desired position (correction signal).

In some embodiments, the ML model could be used to determine a device's calibration parameters. For example, a ML model could be trained using simulated images (either real-space images or two-dimensional Fourier transforms of real-space images) from one or more pre-defined scan patterns with many different calibration parameters (e.g., A, B, C, and/or T described in the Examples section below) and a wide range of simulated specimens for a scanning transmission electron microscope (STEM) or scanning electron microscope (SEM). The regression model could then accept as input a STEM or SEM image acquired with one of the pre-defined scan patterns, and output the predicted calibration parameters for the system or device. Such a ML model may be useful for determining the calibration parameters for any electromagnetic coil hardware.

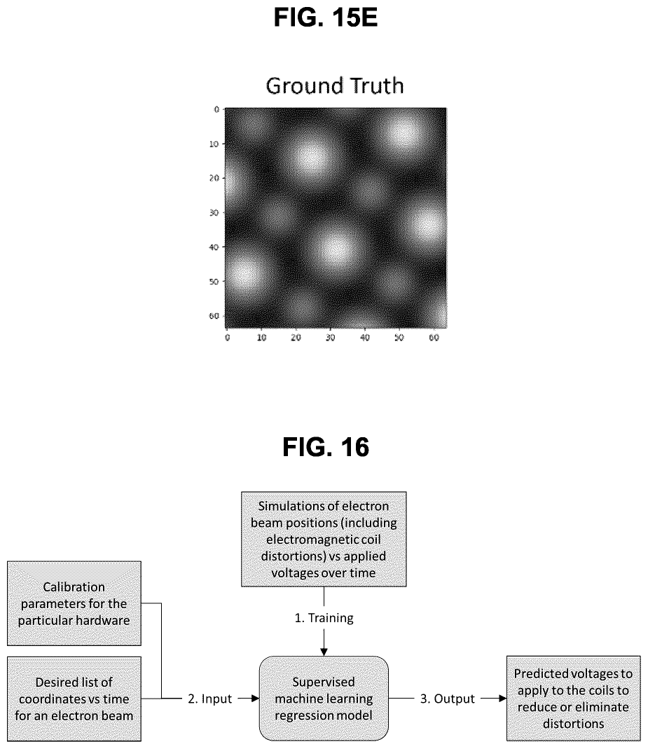

A schematic depiction of an exemplary ML model is presented in FIG. 16, showing the training, input, and output.

In some embodiments, the device includes a beam blanker. Generally, a beam blanker is a device or apparatus that prevents a charged particle beam from reaching a target or substrate. A beam blanker may physically block or intercept the beam prior to reaching the target, deflect the beam away from the target, or some combination of these. A beam blanker may also be referred to as a “shutter” or other similar term. Some beam blankers use electric fields to deflect a charged particle beam. Such a blanker may be referred to as an “electrostatic beam blanker”. An electrostatic beam blanker may deflect the beam completely away from the target or may redirect the beam to a physical object that is not the sample. In general, any suitable type of beam blanker may be used. In some embodiments, the device includes an electrostatic beam blanker. An electrostatic beam blanker may be advantageous because such beam blankers, like electrostatic deflectors, have a fast response time as described above.

In some embodiments, the method includes calculating a beam movement parameter. The beam movement parameter may be calculated based on the director signal, the beam starting position, the beam ending position, the distortion model, some other parameter, or a combination of these. In some embodiments, when the beam movement parameter is high (e.g., above a certain threshold value), the beam blanker could be provided a blank instruction (e.g., from the processing circuitry) that causes the beam blanker to prevent the beam from interacting with the target, sample, or specimen. The beam blanker could be active for a blank period. The blank period could correspond to any suitable period of time, such as a time when the movement parameter is expected or calculated to be above the threshold, an entirety of a time of the beam movement, optionally including a post-movement stabilization period, or some other time.

In some embodiments, when the beam movement parameter is high (e.g., above a certain threshold value), a scan delay could be introduced. The scan delay may be introduced into the director signal, the correction signal, or some other signal or instruction. The scan delay could slow and/or pause a movement of the beam to reduce the beam movement parameter. Such a reduction could be to reduce the beam movement parameter below the threshold.

Delays and/or blanking of the electron beam using a beam blanker, such as an ultra-fast electrostatic beam blanker, may be advantageous to avoid periods of the worst distortions for each scan. For example, the distortion model (e.g., Equation 39 below) would be used to estimate the discrepancy in the position of the electron beam compared to its desired position. This calculation could be based on the average or root-mean-squared deviation from the desired position, or it could be based on the range and/or velocity of movement during the dwell time when the electron beam is desired to be stationary. If the deviation or movement exceeds some threshold, a delay in the pattern of movement could be introduced to allow the electron beam position to stabilize. Additionally or alternatively, during times when the deviation or movement exceeds some threshold, the electron beam could be blanked (turned off, blocked, or deflected) to avoid exposing the electron beam to the specimen during this sub-optimal time.

This may be particularly advantageous for radiation sensitive specimens or for electron beam lithography, electron beam melting, or other techniques where the electron beam induces a change in a target material or specimen. Delaying and/or blanking the electron beam when its position is estimated to deviate from its desired position and/or be unstable based on our distortion model may also prevent artifacts and unwanted electron exposure.

In some embodiments, the beam desired ending position is located in a beam desired ending region. The beam desired ending region can include a plurality of individual beam positions. In some embodiments, the director signal causes the beam director to move the beam of charged particles from the beam starting position to a beam ending position within the beam desired ending region. In some embodiments, the director instruction causes the beam director to scan the beam from the beam ending position to a second position in the beam desired ending region. In some embodiments, the scanning of the beam from the beam ending position to a second position in the beam desired ending region can be included in a correction signal. In some embodiments, the scanning of the beam from the beam ending position to a second position in the beam desired ending region can be performed by the beam director as described above. In some embodiments, the scanning of the beam from the beam ending position to a second position in the beam desired ending region can be performed by the beam corrector as described above.

In some embodiments, the beam is moved to the beam desired ending region using a beam director as described above. In some embodiments, the beam is scanned to locations within the beam desired ending region using a beam corrector as described above. In some embodiments, this beam corrector (e.g., a “scanning beam director”) is an electrostatic beam corrector as described above. An electrostatic beam corrector may be advantageous for fine control, fast response time, or a combination of these.

In general, the beam may be scanned to any number of points within the beam desired ending region. In some embodiments, the beam is scanned within the beam desired ending region so as to form a representative sample of the beam desired ending region.

In some embodiments, the beam may be stationary at a given beam desired ending location or second location within the beam desired ending region. The beam may be stationary for any suitable time period. Such a time period may be referred to as a “point time”, “location time”, “stationary period”, “point dwell time”, or some other term.

In some embodiments, the beam may move continuously to locations within the beam desired ending region.

In some embodiments, the beam may remain within the beam desired ending region for any suitable time period. Such a time period may be referred to as a “dwell time”, “total dwell time”, “region dwell time”, or some other term.

Embodiments of the subject matter and the functional operations described in this specification are implemented by processing circuitry, in tangibly embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory program carrier for execution by, or to control the operation of a data processing apparatus/device (such as the server, the first device 101, or the like). The computer storage medium can be a machine-readable storage device, a machine-readable storage substrate, a random or serial access memory device, or a combination of one or more of them.

The term “data processing apparatus” refers to data processing hardware and can encompass all kinds of apparatus, devices, and machines for processing data, including by way of example a programmable processor, a computer, or multiple processors or computers. The apparatus can also be or further include special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which can also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a computing environment. A computer program can, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA an ASIC.

Computers suitable for the execution of a computer program include, by way of example, general or special purpose microprocessors or both, or any other kind of central processing unit. Generally, a CPU will receive instructions and data from a read-only memory or a random access memory or both. Elements of a computer are a CPU for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., LCD (liquid crystal display) monitor, an LED (light-emitting diode) monitor, a plasma display, an organic LED (OLED) monitor, and the like, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more Such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients (user devices) and servers. A client and server are generally remote from each other and typically interact through a communication network. The relationship of client and server arises by virtue of computer programs running on the respective computers and having a client-server relationship to each other. In an embodiment, a server transmits data, e.g., an HTML page, to a user device, e.g., for purposes of displaying data to and receiving user input from a user interacting with the user device, which acts as a client. Data generated at the user device, e.g., a result of the user interaction, can be received from the user device at the server.

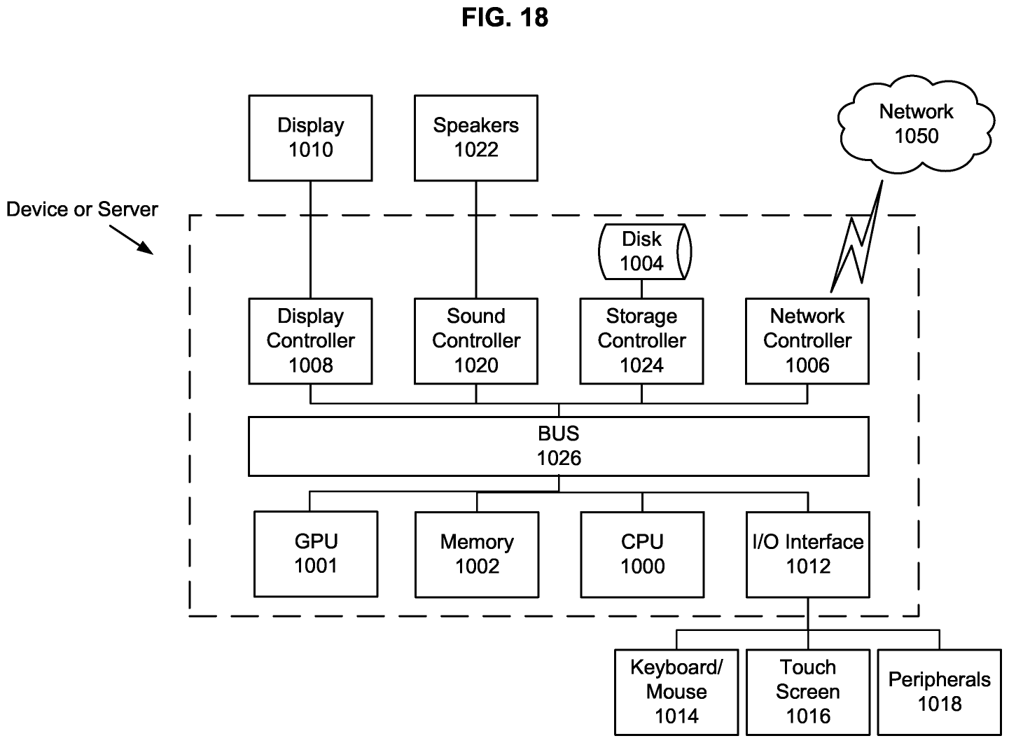

Next, a hardware description of the control device (e.g., a computer) for controlling components of a system including a charged particle beam source according to an embodiment is described with reference to FIG. 18. In FIG. 18, the control device includes a CPU 1000, which performs the processes described above. The control device may contain a GPU 1001 which may perform some or all of the process described above. The control device may contain FPGA(s) or the camera may contain FPGA(s) that perform some or all of the processes described above. The process data and instructions may be stored in memory 1002. These processes and instructions may also be stored on a storage medium disk 1004 such as a hard drive (HDD) or other portable storage medium, or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, or any other information processing device with which the control device communicates, such as a server or computer.

Further, the inventive process may be provided as a utility application, background daemon, or component of an operating system, or combination thereof, executing in conjunction with CPU 1000 and an operating system, such as MICROSOFT WINDOWS®, UNIX®, SOLARIS®, LINUX®, APPLE MAC-OS®, or other systems known to those of ordinary skill in the art.

The hardware elements in order to achieve the control device may be realized by various circuitry elements, known to those of ordinary skill in the art. For example, CPU 1000 may be an INTEL® XEON® or CORE™ processor, an AMD® EPYC® or RYZEN™ processor, an APPLE® M1, M2, M3, or M4 processor, or may be other processor types that would be recognized by those of ordinary skill in the art. Alternatively, the CPU 1000 may be implemented on an FPGA, ASIC, PLD or using discrete logic circuits, as one of ordinary skill in the art would recognize. Further, CPU 1000 may be implemented as multiple processors cooperatively working in parallel to perform the instructions of the inventive processes described above.

The control device in FIG. 18 also includes a network controller 1006, such as an INTEL® PRO® ETHERNET™ network interface card, for interfacing with network 1050. As can be appreciated, the network 1050 can be a public network, such as the internet, or a private network, such as an LAN or WAN network, or any combination thereof, and can also include PSTN or ISDN sub-networks. The network 1050 can also be wired, such as an ETHERNET™ network, or can be wireless, such as a cellular network including EDGE®, LTE®, 3G, 4G®, 5G™, or the like, or such as RF, BLUETOOTH®, or WIFI®, or any other wireless form of communication, as one of ordinary skill in the art would recognize.

The control device further includes a display controller 1008, such as a NVIDIA® GEFORCE® GTX or QUADRO™ graphics adaptor for interfacing with display 1010, such as a HEWLETT PACKARD® Z27q G3 QHD display, a HPL2445w LCD monitor, or any other LCD or LED monitor or display. A general purpose I/O interface 1012 interfaces with a keyboard and/or mouse 1014 as well as a touch screen panel 1016 on or separate from display 1010. General purpose I/O interface 1012 also connects to a variety of peripherals 1018, including any peripherals appropriate for use in electron microscopy.

The general purpose storage controller 1024 connects the storage medium disk 1004 with communication bus 1026, which may be an ISA, EISA, VESA, PCI, or similar, for interconnecting all of the components of the control device. The storage controller may be a RAID controller connected to one or more M.2 or U.2 drives to achieve write speeds high enough to allow continuous acquisition of data from a fast DED camera. A description of the general features and functionality of the display 1010, keyboard and/or mouse 1014, as well as the display controller 1008, storage controller 1024, network controller 1006, sound controller 1020, and general purpose I/O interface 1012 is omitted, as these would be understood by those of ordinary skill in the art.

The present device and method may be advantageous for reducing or eliminating fly-back time for raster scans. Fly-back time is a delay added to the beginning of each scan line to account for scan distortions occurring as the beam moves from the end of one line to the beginning of another. Fly-back time represents overhead that increases the time necessary to scan any two-dimensional area. Fly-back time may also result in unwanted specimen charging or other damage while the charged particle beam is on during the fly-back time. Reducing or eliminating fly-back time will reduce overhead and increase efficiency, as well as potentially reduce specimen charging/damage. Scan distortion correction reduces or eliminates the need for fly-back time.

The present device and method may be advantageous for enabling the use of non-raster patterns—such as a serpentine pattern, spiral pattern, or a variety of fractal patterns.

Such non-raster scan may be useful for reducing dead time between scan lines or for redistributing the application of charged particles on the specimen. Raster scans require time for the beam to move from the end of one line to the beginning of another. Alternative scan patterns can avoid this large jump in the beam position, so that the beam movement from one scan point to the next is smaller or more consistent, making the scan more efficient. Additionally, alternative scan patterns can also distribute the charged particles on the specimen in a different order, resulting in changes to the way the specimen charges (accumulates charge on non-conductive surfaces or volumes), heats, or damages. These effects can either alter the structure in the specimen in an undesirable way or introduce additional distortions by affecting the scattering of the charged particles as they interact with the specimen. Unfortunately, many alternative scan patterns suffer from scan distortions that make them inaccurate, unpredictable, or difficult to use. Scan distortion correction as described herein may enable the use of these alternative scan patterns.

The present device and method may be advantageous for enabling subsampled scan patterns, in which only a fraction of a two-dimensional area is scanned. Subsampling can be useful for reducing the time necessary to scan a two-dimensional area or reducing specimen charging/damage. However, conventional subsampled scan patterns typically have inconsistent distances and directions of beam movement throughout the scan, resulting in noticeable scan distortions. Scan distortion correction as described herein may increase the accuracy of beam positioning, enabling subsampled scan patterns.

The present device and method may be advantageous for enabling intelligent scan patterns whereby information collected during the course of a scan leads to real-time updates to the scan pattern. Intelligent updates may include moving to identified regions of interest or avoiding regions that are not of interest thereby increasing efficiency of a measurement, adjusting dwell time and/or position to affect quality in additive manufacturing or e-beam welding, or adjusting position and dwell time in e-beam lithography to improve the quality of the pattern. Inconsistent motions and dwell times may not be possible to achieve without scan distortion corrections such as those described herein.

While this specification contains many specific implementation details, these should not be construed as limitations on the scope of what can be claimed, but rather as descriptions of features that can be specific to particular embodiments.

Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features can be described above as acting in certain combinations and even initially claimed as such, one or more features from a claimed combination can in some cases be excised from the combination, and the claimed combination can be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

Numerous modifications and variations of the present invention are possible in light of the above teachings. It is therefore to be understood that, within the scope of the appended claims, the invention may be practiced otherwise than as specifically described herein.

The examples below are intended to further illustrate protocols for constructing and/or operating the device and/or performing the method of distortion correction and are not intended to limit the scope of the claims.

Embodiments of the present disclosure may also be as set forth in the following parentheticals.

(1) A charged particle beam device, comprising a charged particle source configured to produce a beam of charged particles; a beam director configured to direct the beam of charged particles to a target; and processing circuitry configured to receive a beam desired ending position, receive a beam starting position, calculate a director signal based on the beam starting position and the beam desired ending position, calculate a corrected signal based on the beam starting position, the director signal, a distortion model, and the beam desired ending position, and transmit an instruction including the corrected signal to the beam director, wherein the corrected signal causes the beam director to move the beam of charged particles from the beam starting position to a beam corrected ending position.

(2) The charged particle beam device according to (1), wherein the charged particles are electrons.

(3) The charged particle beam device according to (1) or (2), wherein the processing circuitry is further configured to receive a beam position history, and wherein the corrected signal is calculated based on the beam starting position, the director signal, the distortion model, the beam desired ending position, and the beam position history.

(4) The charged particle beam device according to any one of (1) to (3), wherein the processing circuitry is configured to calculate a plurality of corrected signals, each corresponding to a preselected beam desired ending position and the instruction includes the plurality of corrected signals.

(5) The charged particle beam device according to (4), wherein the plurality of corrected signals is an ordered list where each beam starting position corresponds to an immediately preceding beam desired ending position.

(6) The charged particle beam device according to any one of (1) to (5), further comprising a beam position detector, wherein the beam starting position is received from the beam position detector.

(7) The charged particle beam device according to (6), wherein the processing circuitry is configured to transmit the instruction including the corrected signal to the beam director prior to receiving a subsequent beam position.

(8) The charged particle beam device according to any one of (1) to (7), wherein the processing circuitry is configured to calculate at least one parameter selected from the group consisting of the director signal and the corrected signal using a machine learning model.

(9) The charged particle beam device according to (8), wherein the machine learning model is trained using a training set that includes a plurality of director signals and a plurality of beam positions.

(10) The charged particle beam device according to any one of (1) to (9), wherein the processing circuitry is further configured to calculate a beam uncorrected ending position based on the beam starting position, the director signal, and a distortion model, and wherein the corrected signal is calculated based on the beam starting position, the director signal, a distortion model, the beam desired ending position, and the beam uncorrected ending position.

(11) A method of directing a beam of charged particles, the method comprising passing the beam of charged particles through a beam director; receiving a beam desired ending position; receiving a beam starting position; calculating a director signal based on the beam starting position and the beam desired ending position, calculating a corrected signal based on the beam starting position, the director signal, a distortion model, and the beam desired ending position, and transmitting an instruction including the corrected signal to the beam director, wherein the corrected signal causes the beam director to move the beam of charged particles from the beam starting position to a beam corrected ending position.

(12) The method according to (11), wherein the charged particles are electrons.

(13) The method according to (11) or (12), further comprising receiving a beam position history, wherein the corrected signal is calculated based on the beam starting position, the director signal, the distortion model, the beam desired ending position, and the beam position history.

(14) The method according to any one of (11) to (13), further comprising calculating a plurality of corrected signals, each corresponding to a preselected beam desired ending position and the instruction includes the plurality of corrected signals.

(15) The method according to (14), wherein the plurality of corrected signals is an ordered list where each beam starting position corresponds to an immediately preceding beam desired ending position.

(16) The method according to any one of (11) to (15), wherein the beam starting position is received from a beam position detector.

(17) The method according to (16), wherein the transmitting the instruction including the corrected signal to the beam director is performed before receiving a subsequent beam position.

(18) The method according to any one of (11) to (17), wherein at least one parameter selected from the group consisting of the director signal and the corrected signal is calculated using a machine learning model.

(19) The method according to (18), wherein the machine learning model is trained using a training set that includes a plurality of director signals and a plurality of beam positions.

(20) The method according to any one of (11) to (19), further comprising calculating a beam uncorrected ending position based on the beam starting position, the director signal, and a distortion model, wherein the corrected signal is calculated based on the beam starting position, the director signal, a distortion model, the beam desired ending position, and the beam uncorrected ending position.

(21) A non-transitory computer-readable medium having stored thereon, computer executable instructions, which when executed by a computer, cause the computer to execute operations, the operations comprising receiving a beam desired ending position; receiving a beam starting position; calculating a director signal based on the beam starting position and the beam desired ending position, calculating a corrected signal based on the beam starting position, the director signal, a distortion model, and the beam desired ending position, and transmitting an instruction including the corrected signal to a beam director, wherein the corrected signal causes the beam director to move a beam of charged particles passing therethrough from the beam starting position to a beam corrected ending position.

(22) The non-transitory computer-readable medium according to (21), wherein the charged particles are electrons.

(23) The non-transitory computer-readable medium according to (21) or (22), wherein the operations further comprise receiving a beam position history, and wherein the corrected signal is calculated based on the beam starting position, the director signal, the distortion model, the beam desired ending position, and the beam position history.

(24) The non-transitory computer-readable medium according to any one of (21) to (23), wherein the operations further comprise calculating a plurality of corrected signals, each corresponding to a preselected beam desired ending position and the instruction includes the plurality of corrected signals.

(25) The non-transitory computer-readable medium according to (24), wherein the plurality of corrected signals is an ordered list where each beam starting position corresponds to an immediately preceding beam desired ending position.

(26) The non-transitory computer-readable medium according to any one of (21) to (25), wherein the beam starting position is received from a beam position detector.

(27) The non-transitory computer-readable medium according to (26), wherein the transmitting the instruction including the corrected signal to the beam director is performed before receiving a subsequent beam position.

(28) The non-transitory computer-readable medium according to any one of (21) to (27), wherein at least one parameter selected from the group consisting of the director signal and the corrected signal is calculated using a machine learning model.

(29) The non-transitory computer-readable medium according to (28), wherein the machine learning model is trained using a training set that includes a plurality of director signals and a plurality of beam positions.

(30) The non-transitory computer-readable medium according to any one of (21) to (29), wherein the operations further comprise calculating a beam uncorrected ending position based on the beam starting position, the director signal, and a distortion model, and wherein the corrected signal is calculated based on the beam starting position, the director signal, a distortion model, the beam desired ending position, and the beam uncorrected ending position.

(31) A charged particle beam device, comprising a charged particle source configured to produce a beam of charged particles; a beam director configured to direct the beam of charged particles to produce a directed beam; a beam corrector configured to provide a direction correction to the directed beam; and processing circuitry configured to: receive a beam desired ending position, receive a beam starting position, calculate a director signal based on the beam starting position and the beam desired ending position, transmit a director instruction including the director signal to the beam director, calculate a corrector signal based on the beam starting position, the director signal, a distortion model, and the beam desired ending position, and transmit a corrector instruction including the corrector signal to the beam corrector, wherein the director signal causes the beam director to move the beam of charged particles, wherein the corrector signal causes the beam corrector to move the beam of charged particles, and wherein the beam director and beam corrector move the beam of charged particles from the beam starting position to a beam corrected ending position.

(32) The charged particle beam device according to (31), wherein the charged particles are electrons.

(33) The charged particle beam device according to (31) or (32), wherein the processing circuitry is further configured to receive a beam position history, and wherein the corrector signal is calculated based on the beam starting position, the director signal, the distortion model, the beam desired ending position, and the beam position history.

(34) The charged particle beam device according to any one of (31) to (33), wherein the processing circuitry is configured to calculate a plurality of director signals and a plurality of corrector signals, each director signal corresponding to a corrector signal to create a plurality of pairs, each pair corresponding to a preselected beam desired ending position, wherein the director instruction includes the plurality of director signals, and wherein the corrector instruction includes the plurality of corrector signals.

(35) The charged particle beam device according to (34), wherein the plurality of pairs is an ordered list where each beam starting position corresponds to an immediately preceding beam desired ending position.

(36) The charged particle beam device according to any one of (31) to (35), further comprising a beam position detector, wherein the beam starting position is received from the beam position detector.

(37) The charged particle beam device according to (36), wherein the processing circuitry is configured to transmit the corrector instruction including the corrector signal to the beam corrector prior to receiving a subsequent beam position.

(38) The charged particle beam device according to any one of (31) to (37), wherein the processing circuitry is configured to calculate at least one parameter selected from the group consisting of the director signal and the corrector signal using a machine learning model.

(39) The charged particle beam device according to (38), wherein the machine learning model is trained using a training set that includes a plurality of director signals, a plurality of corrector signals, and a plurality of beam positions.

(40) The charged particle beam device according to any one of (31) to (39), wherein the processing circuitry is further configured to calculate a beam uncorrected ending position based on the beam starting position, the director signal, and a distortion model, and wherein the corrector signal is calculated based on the beam starting position, the director signal, a distortion model, the beam desired ending position, and the beam uncorrected ending position.

(41) A method of directing a beam of charged particles, the method comprising passing the beam of charged particles through a beam director; receiving a beam desired ending position, receiving a beam starting position, calculating a director signal based on the beam starting position and the beam desired ending position, transmitting a director instruction including the director signal to a beam director, calculating a corrector signal based on the beam starting position, the director signal, a distortion model, and the beam desired ending position, and transmitting a corrector instruction including the corrector signal to a beam corrector, wherein the director signal causes the beam director to move the beam of charged particles, wherein the corrector signal causes the beam corrector to move the beam of charged particles, and wherein the beam director and beam corrector move the beam of charged particles from the beam starting position to a beam corrected ending position.

(42) The method according to (41), wherein the charged particles are electrons.

(43) The method according to (41) or (42), further comprising receiving a beam position history, wherein the corrector signal is calculated based on the beam starting position, the director signal, the distortion model, the beam desired ending position, and the beam position history.

(44) The method according to any one of (41) to (43), further comprising calculating a plurality of director signals and a plurality of corrector signals, each director signal corresponding to a corrector signal to create a plurality of pairs, each pair corresponding to a preselected beam desired ending position; the director instruction includes the plurality of director signals; and the corrector instruction includes the plurality of corrector signals.

(45) The method according to (44), wherein the plurality of pairs is an ordered list where each beam starting position corresponds to an immediately preceding beam desired ending position.

(46) The method according to any one of (41) to (45), wherein the beam starting position is received from a beam position detector.

(47) The method according to (46), wherein the transmitting the corrector instruction including the corrector signal to the beam corrector is performed before receiving a subsequent beam position.

(48) The method according to any one of (41) to (47), wherein at least one parameter selected from the group consisting of the director signal and the corrector signal is calculated using a machine learning model.

(49) The method according to (48), wherein the machine learning model is trained using a training set that includes a plurality of director signals, a plurality of corrector signals, and a plurality of beam positions.

(50) The method according to any one of (41) to (49), further comprising calculating a beam uncorrected ending position based on the beam starting position, the director signal, and a distortion model, wherein the corrector signal is calculated based on the beam starting position, the director signal, a distortion model, the beam desired ending position, and the beam uncorrected ending position.

(51) A non-transitory computer-readable medium having stored thereon, computer executable instructions, which when executed by a computer, cause the computer to execute operations, the operations comprising receiving a beam desired ending position, receiving a beam starting position, calculating a director signal based on the beam starting position and the beam desired ending position, transmitting a director instruction including the director signal to a beam director, calculating a corrector signal based on the beam starting position, the director signal, a distortion model, and the beam desired ending position, and transmitting a corrector instruction including the corrector signal to a beam corrector, wherein the director signal causes the beam director to move a beam of charged particles, wherein the corrector signal causes the beam corrector to move the beam of charged particles, and wherein the beam director and beam corrector move the beam of charged particles from the beam starting position to a beam corrected ending position.

(52) The non-transitory computer-readable medium according to (51), wherein the charged particles are electrons.

(53) The non-transitory computer-readable medium according to (51) or (52), wherein the operations further comprise receiving a beam position history, and wherein the corrector signal is calculated based on the beam starting position, the director signal, the distortion model, the beam desired ending position, and the beam position history.

(54) The non-transitory computer-readable medium according to any one of (51) to (53), wherein the operations further comprise calculating a plurality of director signals and a plurality of corrector signals, each director signal corresponding to a corrector signal to create a plurality of pairs, each pair corresponding to a preselected beam desired ending position, wherein the director instruction includes the plurality of director signals, and wherein the corrector instruction includes the plurality of corrector signals.

(55) The non-transitory computer-readable medium according to (54), wherein the plurality of pairs is an ordered list where each beam starting position corresponds to an immediately preceding beam desired ending position.

(56) The non-transitory computer-readable medium according to any one of (51) to (55), wherein the beam starting position is received from a beam position detector.

(57) The non-transitory computer-readable medium according to (56), wherein the transmitting the corrector instruction including the corrector signal to the beam corrector is performed before receiving a subsequent beam position.

(58) The non-transitory computer-readable medium according to any one of (51) to (57), wherein at least one parameter selected from the group consisting of the director signal and the corrector signal is calculated using a machine learning model.

(59) The non-transitory computer-readable medium according to (58), wherein the machine learning model is trained using a training set that includes a plurality of director signals, a plurality of corrector signals, and a plurality of beam positions.

(60) The non-transitory computer-readable medium according to any one of (51) to (59), wherein the operations further comprise calculating a beam uncorrected ending position based on the beam starting position, the director signal, and a distortion model, and wherein the corrector signal is calculated based on the beam starting position, the director signal, a distortion model, the beam desired ending position, and the beam uncorrected ending position.

(61) A charged particle beam device, comprising a charged particle source configured to produce a beam of charged particles; a beam director configured to direct the beam of charged particles to produce a directed beam; a beam blanker; and processing circuitry configured to receive a beam desired ending position, receive a beam starting position, calculate a director signal based on the beam starting position and the beam desired ending position, calculate a beam movement parameter based on the director signal, the beam starting position, and the beam ending position, when the beam movement parameter is above a threshold movement value, transmit to the beam blanker a blank instruction including a blank signal that causes the beam blanker to prevent the beam from interacting with a target for a blank period, and transmit a director instruction including the director signal to the beam director, wherein the director signal causes the beam director to move the beam of charged particles from the beam starting position to the beam desired ending position.

(62) The charged particle beam device according to (61), wherein the charged particles are electrons.

(63) The charged particle beam device according to (61) or (62), wherein the blank period is an estimated time required for the beam director to move the beam of charged particles from the beam starting position to the beam desired ending position.

(64) The charged particle beam device according to any one of (61) to (63), wherein the processing circuitry is further configured to calculate a beam uncorrected ending position based on the beam starting position, the director signal, and a distortion model, calculate a corrected signal based on the beam uncorrected ending position, the director signal, and the beam desired ending position, and transmit a correction instruction including corrected signal to the beam director, wherein the corrected signal causes the beam director to move the beam of charged particles from the beam uncorrected ending position to a beam corrected ending position.

(65) The charged particle beam device according to any one of (61) to (64), further comprising a beam corrector configured to provide a direction correction to the directed beam, wherein the processing circuitry is further configured to calculate a beam uncorrected ending position based on the beam starting position, the director signal, and a distortion model, calculate a corrector signal based on the beam uncorrected ending position and the beam desired ending position, and transmit a corrector instruction including the corrector signal to the beam corrector, wherein the corrector signal causes the beam corrector to move the beam of charged particles from the uncorrected ending position to a beam corrected ending position.

(66) The charged particle beam device according to (65), wherein the blank period corresponds to an estimated time required for the beam director to move the beam of charged particles from the beam starting position to the beam corrected ending position.

(67) The charged particle beam device of any one of (64) to (66), wherein the processing circuitry is further configured to receive a beam position history, and wherein the beam uncorrected ending position is calculated based on the beam starting position, the director signal, the distortion model, and the beam position history.

(68) The charged particle beam device according to any one of (65) to (66), wherein the processing circuitry is further configured to receive a beam position history, and wherein the beam uncorrected ending position is calculated based on the beam starting position, the director signal, the distortion model, and the beam position history.

(69) The charged particle beam device according to any one of (61) to (68), wherein the processing circuitry is configured to calculate a plurality of director signals, each corresponding to a preselected beam desired ending position and a plurality of movement parameters, each corresponding to a preselected beam desired ending position, wherein each director signal corresponding to a movement parameter to create a plurality of pairs, each pair corresponding to a preselected beam desired ending position, wherein the director instruction includes the plurality of director signals, and wherein the blank instruction includes a plurality of blank signals, each blank signal corresponding to a movement parameter above the threshold movement value.

(70) The charged particle beam device according to (69), wherein the plurality of pairs is an ordered list where each beam starting position corresponds to an immediately preceding beam desired ending position.

(71) The charged particle beam device according to any one of (61) to (70), further comprising a beam position detector, wherein the beam starting position is received from the beam position detector.

(72) The charged particle beam device according to (71), wherein the processing circuitry is configured to transmit the director instruction including the director signal to the beam director prior to receiving a subsequent beam position.

(73) The charged particle beam device according to any one of (61) to (72), wherein the processing circuitry is further configured to calculate at least one parameter selected from the group consisting of the director signal and the beam movement parameter using a machine learning model.

(74) The charged particle beam device according to any one of (64) to (73), wherein the processing circuitry is further configured to calculate the corrected signal using a machine learning model.

(75) The charged particle beam device according to any one of (65) to (73), wherein the processing circuitry is further configured to calculate the corrector signal using a machine learning model.

(76) A method of directing a beam of charged particles, the method comprising passing the beam of charged particles through a beam director; receiving a beam desired ending position; receiving a beam starting position; calculating a director signal based on the beam starting position and the beam desired ending position; calculating a beam movement parameter based on the director signal, the beam starting position, and the beam ending position; when the beam movement parameter is above a threshold movement value, transmitting to a beam blanker a blank instruction including a blank signal that causes the beam blanker to prevent the beam from interacting with a target for a blank period; and transmitting a director instruction including the director signal to the beam director, wherein the director signal causes the beam director to move the beam of charged particles from the beam starting position to the beam desired ending position.

(77) The method according to (76), wherein the charged particles are electrons.

(78) The method according to (76) or (77), wherein the blank period is an estimated time required for the beam director to move the beam of charged particles from the beam starting position to the beam desired ending position.

(79) The method according to any one of (76) to (78), further comprising calculating a beam uncorrected ending position based on the beam starting position, the director signal, and a distortion model; calculating a corrected signal based on the beam uncorrected ending position, the director signal, and the beam desired ending position; and transmitting a correction instruction including corrected signal to the beam director, wherein the corrected signal causes the beam director to move the beam of charged particles from the beam uncorrected ending position to a beam corrected ending position.

(80) The method according to any one of (76) to (78), further comprising calculating a beam uncorrected ending position based on the beam starting position, the director signal, and a distortion model; calculating a corrector signal based on the beam uncorrected ending position and the beam desired ending position; and transmitting a corrector instruction including the corrector signal to a beam corrector, wherein the corrector signal causes the beam corrector to move the beam of charged particles from the uncorrected ending position to a beam corrected ending position.

(81) The method according to (80), wherein the blank period corresponds to an estimated time required for the beam director to move the beam of charged particles from the beam starting position to the beam corrected ending position.

(82) The method according to any one of (79) to (81), further comprising receiving a beam position history, wherein the beam uncorrected ending position is calculated based on the beam starting position, the director signal, the distortion model, and the beam position history.

(83) The method according to any one of (80) to (82), further comprising receiving a beam position history, wherein the beam uncorrected ending position is calculated based on the beam starting position, the director signal, the distortion model, and the beam position history.

(84) The method according to any one of (76) to (83), further comprising calculating a plurality of director signals, each corresponding to a preselected beam desired ending position and a plurality of movement parameters, each corresponding to a preselected beam desired ending position, wherein each director signal corresponding to a movement parameter to create a plurality of pairs, each pair corresponding to a preselected beam desired ending position, wherein the director instruction includes the plurality of director signals, and wherein the blank instruction includes a plurality of blank signals, each blank signal corresponding to a movement parameter above the threshold movement value.

(85) The method according to (84), wherein the plurality of pairs is an ordered list where each beam starting position corresponds to an immediately preceding beam desired ending position.

(86) The method according to any one of (76) to (85), wherein the beam starting position is received from a beam position detector.

(87) The method according to (86), wherein the transmitting the director instruction including the director signal to the beam director is performed before receiving a subsequent beam position.

(88) The method according to any one of (76) to (87), wherein at least one value selected from the group consisting of the director signal and the beam movement parameter is calculated using a machine learning model.

(89) The method according to any one of (79) to (88), wherein the corrected signal is calculated using a machine learning model.

(90) The method according to any one of (80) to (89), wherein the corrector signal is calculated using a machine learning model.

(91) A non-transitory computer-readable medium having stored thereon, computer executable instructions, which when executed by a computer, cause the computer to execute operations, the operations comprising receiving a beam desired ending position; receiving a beam starting position; calculating a director signal based on the beam starting position and the beam desired ending position; calculating a beam movement parameter based on the director signal, the beam starting position, and the beam ending position; when the beam movement parameter is above a threshold movement value, transmitting to a beam blanker a blank instruction including a blank signal that causes the beam blanker to prevent a beam of charged particles from interacting with a target for a blank period; and transmitting a director instruction including the director signal to a beam director through which the beam of charged particles is passing, wherein the director signal causes the beam director to move the beam of charged particles from the beam starting position to the beam desired ending position.

(92) The non-transitory computer-readable medium according to (91), wherein the charged particles are electrons.

(93) The non-transitory computer-readable medium according to (91) or (92), wherein the blank period is an estimated time required for the beam director to move the beam of charged particles from the beam starting position to the beam desired ending position.

(94) The non-transitory computer-readable medium according to any one of (91) to (93), wherein the operations further comprise calculating a beam uncorrected ending position based on the beam starting position, the director signal, and a distortion model; calculating a corrected signal based on the beam uncorrected ending position, the director signal, and the beam desired ending position; and transmitting a correction instruction including corrected signal to the beam director, and wherein the corrected signal causes the beam director to move the beam of charged particles from the beam uncorrected ending position to a beam corrected ending position.

(95) The non-transitory computer-readable medium according to any one of (91) to (94), wherein the operations further comprise calculating a beam uncorrected ending position based on the beam starting position, the director signal, and a distortion model; calculating a corrector signal based on the beam uncorrected ending position and the beam desired ending position; and transmitting a corrector instruction including the corrector signal to a beam corrector, and wherein the corrector signal causes the beam corrector to move the beam of charged particles from the uncorrected ending position to a beam corrected ending position.

(96) The non-transitory computer-readable medium according to (95), wherein the blank period corresponds to an estimated time required for the beam director to move the beam of charged particles from the beam starting position to the beam corrected ending position.

(97) The non-transitory computer-readable medium according to any one of (94) to (96), wherein the operations further comprise receiving a beam position history, and wherein the beam uncorrected ending position is calculated based on the beam starting position, the director signal, the distortion model, and the beam position history.

(98) The non-transitory computer-readable medium according to any one of (96) to (97), wherein the operations further comprise receiving a beam position history, and wherein the beam uncorrected ending position is calculated based on the beam starting position, the director signal, the distortion model, and the beam position history.

(99) The non-transitory computer-readable medium according to any one of (91) to (98), wherein the operations further comprise calculating a plurality of director signals, each corresponding to a preselected beam desired ending position and a plurality of movement parameters, each corresponding to a preselected beam desired ending position, wherein each director signal corresponding to a movement parameter to create a plurality of pairs, each pair corresponding to a preselected beam desired ending position, wherein the director instruction includes the plurality of director signals, and wherein the blank instruction includes a plurality of blank signals, each blank signal corresponding to a movement parameter above the threshold movement value.

(100) The non-transitory computer-readable medium according to (99), wherein the plurality of pairs is an ordered list where each beam starting position corresponds to an immediately preceding beam desired ending position.

(101) The non-transitory computer-readable medium according any one of (91) to (100), wherein the beam starting position is received from a beam position detector.

(102) The non-transitory computer-readable medium according to (101), wherein the transmitting the director instruction including the director signal to the beam director is performed before receiving a subsequent beam position.

(103) The non-transitory computer-readable medium according to any one of (91) to (102), wherein at least one value selected from the group consisting of the director signal and the beam movement parameter is calculated using a machine learning model.

(104) The non-transitory computer-readable medium according to any one of (94) to (103), wherein the corrected signal is calculated using a machine learning model.

(105) The non-transitory computer-readable medium according to any one of (95) to (104), wherein the corrector signal is calculated using a machine learning model.

(105) A charged particle beam device, comprising a charged particle source configured to produce a beam of charged particles; a beam director configured to direct the beam of charged particles to a target; and processing circuitry configured to receive a beam desired ending region, receive a beam starting position, calculate a director signal based on the beam starting position and the beam desired ending region, and transmit a director instruction including the director signal to the beam director, wherein the director signal causes the beam director to move the beam of charged particles from the beam starting position to a beam ending position within the beam desired ending region, and wherein the director instruction causes the beam director to scan the beam from the beam ending position to a second position in the beam desired ending region.

(106) The charged particle beam device according to (105), wherein the charged particles are electrons.

(107) The charged particle beam device according to (105) or (106), wherein the beam is scanned to a plurality of positions in the beam desired ending region.

(108) The charged particle beam device according to any one of (105) to (107), wherein the beam remains within the beam desired ending region for a total dwell time.

(109) The charged particle beam device according to (108), wherein the beam moves continuously within the beam desired ending region for the total dwell time.

(110) The charged particle beam device according to any one of (105) to (109), wherein the beam director includes a first electromagnetic director configured to control the beam of charged particles along a first direction and a second electromagnetic director configured to control the beam of charged particles along a second direction; a first electrostatic director configured to control the beam of charged particles along the first direction and a second electrostatic director configured to control the beam of charged particles along the second direction, wherein the first direction is substantially perpendicular to the second direction, and wherein the beam director moves the beam of charged particles from the beam starting position to a beam ending position within the beam desired ending region using the first electromagnetic director and second electromagnetic director and scans the beam from the beam ending position to a second position in the beam desired ending region using the first electrostatic director and second electrostatic director.

(111) The charged particle beam device according to any one of (105) to (110), wherein the beam is scanned within the beam desired ending region so as to form a representative sample of the beam desired ending region.

(112) A method of directing a beam of charged particles, the method comprising receiving a beam desired ending region; receiving a beam starting position; calculating a director signal based on the beam starting position and the beam desired ending region; and transmitting a director instruction including the director signal to a beam director, wherein the director signal causes the beam director to move the beam of charged particles from the beam starting position to a beam ending position within the beam desired ending region, and wherein the director instruction causes the beam director to scan the beam from the beam ending position to a second position in the beam desired ending region.

(113) The method according to (112), wherein the charged particles are electrons.

(114) The method according to (112) or (113), wherein the beam is scanned to a plurality of positions in the beam desired ending region.

(115) The method according to any one of (112) to (114), wherein the beam remains within the beam desired ending region for a total dwell time.

(116) The method according to any one of (112) to (115), wherein the beam moves continuously within the beam desired ending region for the total dwell time.

(117) The method according to any one of (112) to (116), wherein the beam director includes a first electromagnetic director configured to control the beam of charged particles along a first direction and a second electromagnetic director configured to control the beam of charged particles along a second direction; and a first electrostatic director configured to control the beam of charged particles along the first direction and a second electrostatic director configured to control the beam of charged particles along the second direction, wherein the first direction is substantially perpendicular to the second direction, and wherein the beam director moves the beam of charged particles from the beam starting position to a beam ending position within the beam desired ending region using the first electromagnetic director and second electromagnetic director and scans the beam from the beam ending position to a second position in the beam desired ending region using the first electrostatic director and second electrostatic director.

(118) The method according to any one of (112) to (117), wherein the beam is scanned within the beam desired ending region so as to form a representative sample of the beam desired ending region.

(119) A non-transitory computer-readable medium having stored thereon, computer executable instructions, which when executed by a computer, cause the computer to execute operations, the operations comprising receiving a beam desired ending region; receiving a beam starting position; calculating a director signal based on the beam starting position and the beam desired ending region; and transmitting a director instruction including the director signal to a beam director, wherein the director signal causes the beam director to move a beam of charged particles passing therethrough from the beam starting position to a beam ending position within the beam desired ending region, and wherein the director instruction causes the beam director to scan the beam from the beam ending position to a second position in the beam desired ending region.

(120) The non-transitory computer-readable medium according to (119), wherein the charged particles are electrons.

(121) The non-transitory computer-readable medium according to (119) or (120), wherein the beam is scanned to a plurality of positions in the beam desired ending region.

(122) The non-transitory computer-readable medium according to any one of (119) to (121), wherein the beam remains within the beam desired ending region for a total dwell time.

(123) The non-transitory computer-readable medium according to (122), wherein the beam moves continuously within the beam desired ending region for the total dwell time.

(124) The non-transitory computer-readable medium according to any one of (119) to (123), wherein the beam director includes a first electromagnetic director configured to control the beam of charged particles along a first direction and a second electromagnetic director configured to control the beam of charged particles along a second direction; and a first electrostatic director configured to control the beam of charged particles along the first direction and a second electrostatic director configured to control the beam of charged particles along the second direction, wherein the first direction is substantially perpendicular to the second direction, and wherein the beam director moves the beam of charged particles from the beam starting position to a beam ending position within the beam desired ending region using the first electromagnetic director and second electromagnetic director and scans the beam from the beam ending position to a second position in the beam desired ending region using the first electrostatic director and second electrostatic director.

(125) The non-transitory computer-readable medium according to any one of (119) to (124), wherein the beam is scanned within the beam desired ending region so as to form a representative sample of the beam desired ending region.

### Examples

To theoretically model scan distortions, an exemplary distortion model is provided as follows. Consider an electromagnetic electron deflector capable of deflecting an electron beam along two axes (e.g., the exemplary deflector shown in FIG. 2A). The Lorentz force law (Equation 1) describes the force that a charged particle experiences due to electromagnetic fields:

$$F = q ( E + v \times B ) \qquad ( 1 )$$

where B is magnetic field, E is the electric field, v is the velocity of the charged particle, and q is the charge of the particle. In this geometry, the electric field is negligible, and therefore Equation 1 may be simplified to Equation 2.

$$F = q ( v \times B ) \qquad ( 2 )$$

The geometry of the deflector is such that v and B are orthogonal, with B in the xy-plane. Therefore, Equation 2 can be divided into an x-component (Equation 3a) and a y-component (Equation 3b):

$${F}_{x} = - {qvB}_{y} \qquad ( 3 a )$$

$${F}_{y} = {qvB}_{x} \qquad ( 3 b )$$

With respect to the moving electrons, the magnetic field can be approximated as a uniform magnetic field constrained to a rectangular volume in the middle of the deflector (FIG. 2B) with thickness d_{D}. Then the deflection angle of the electron by the deflector can be calculated using Equations 4a and 4b:

$${θ}_{x} = {tan}^{- 1} ( \frac{{F}_{x} {d}_{D}}{{v}^{2} m} ) = {tan}^{- 1} ( \frac{- q {d}_{D} {B}_{y}}{v m} ) \qquad ( 4 a )$$

$${θ}_{y} = {tan}^{- 1} ( \frac{{F}_{y} {d}_{D}}{{v}^{2} m} ) = {tan}^{- 1} ( \frac{q {d}_{D} {B}_{X}}{v m} ) \qquad ( 4 b )$$

where m is the mass of the charged particle.

Because the deflection angles will be very small, the small angle approximation may be applied, simplifying to Equations 5a and 5b:

$${θ}_{x} \approx \frac{- q {d}_{D}}{v m} {B}_{y} \qquad ( 5 a )$$

$${θ}_{y} \approx \frac{q {d}_{D}}{v m} {B}_{x} \qquad ( 5 b )$$

Again, using the small angle approximation, the displacement of the electron beam on the specimen due to this deflection angle is given by Equations 6a and 6b:

$$x \approx \frac{- q {d}_{D} {d}_{S}}{v m} {B}_{y} \qquad ( 6 a )$$

$$y \approx \frac{q {d}_{D} {d}_{S}}{v m} {B}_{χ} \qquad ( 6 b )$$

where d_{S} is the distance from the deflector to the specimen.

For any given device operating at a given accelerating voltage, the following quantity will be a constant, which is defined according to Equation 7:

$${A}_{dis} = \frac{q {d}_{D} {d}_{S}}{v m} \qquad ( 7 )$$

The displacement of the electron beam on the specimen is directly proportional to the magnetic field in the deflector. The definition of the positive x and y directions on the specimen are also arbitrary, so the negative sign in Equation 6a may be ignored.

Therefore, the displacement may be given by Equations 8a and 8b:

$$x \approx {A}_{d i s} {B}_{y} \qquad ( 8 a )$$

$$y \approx {A}_{d i s} {B}_{x} \qquad ( 8 b )$$

The magnetic field is generated by a combination of the electric current in the deflector and changes in the electric fields in the deflector, which is described by Maxwell's formulation of Ampère's law (Equation 9):

$$∇ \times B = μ J + μϵ \frac{\partial E}{\partial t} \qquad ( 9 )$$

where J is the current density, u is the magnetic constant, and e is the permittivity. Integration of Equation 9 yields Equation 10:

$$\int ( ∇ \times B ) \cdot da = ∮ B \cdot dl = μ \int J \cdot da + μϵ \int \frac{\partial E}{\partial t} \cdot da \qquad ( 10 )$$

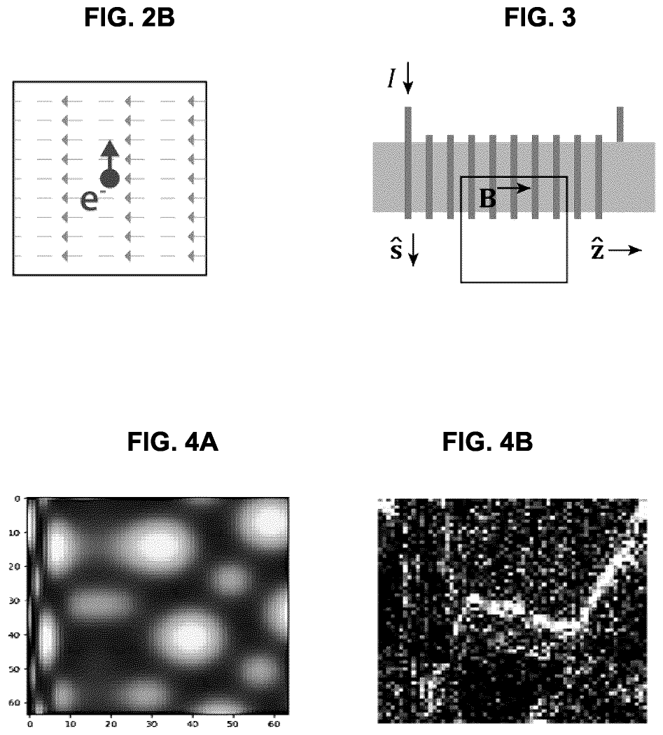

In each of the deflector coils, the current/electric field is circumferential, so that at all points equidistant from the ends of a deflector coil the magnetic field is parallel with the axis of the coil (FIG. 3).

Because the electron beam diameter is much smaller than the length of each deflector coil and equidistant from each end of each deflector coil, the ends of each deflector coil may be ignored for the purposes of calculating the magnetic field at the center of each deflector coil.

Since the deflector coil is not infinitely long, the magnetic field outside each deflector coil will be non-zero (which is the desired behavior). The strength of the magnetic field at a point r from the middle-center of the deflector coil is proportional to the magnetic field at its middle-center is given by Equation 11:

$$B ( k ) = \{ \begin{matrix}{A}_{B} ( k ) \cdot {B}_{0} , & inside coil \\ 0 , & at edge of coil \\ - {A}_{B} ( k ) \cdot {B}_{0} , & outside coil\end{matrix} \qquad ( 11 )$$

where A_{B}(k) is a positive scalar function with values in the range [0,−1], k is a vector from the middle center of the deflector coil to the coordinates of interest, and Bo is the strength of the magnetic field in the middle center of the deflector coil.

In the steady state, and independent of the other deflector coils, the magnetic field in the middle center of the deflector coil directly generated by its input voltage is given by Equation 12:

$${B}_{0} = ∮ B \cdot dl = μ \int J \cdot da = μ nI \hat{z} = \frac{μ n {V}_{i n}}{R} \hat{z} \qquad ( 12 )$$

where \hat{z} is the unit vector along the axis of the cylindrical deflector coil (FIG. 3), n is the number of wire turns per unit length around each deflector coil, I is the applied current, V is the applied voltage, and R is the resistance of the coil wires.

The resistance and inductance of the deflector coil wires cause a non-instantaneous response in the input voltage. The actual voltage with respect to time that is experienced in the deflector coil is the input voltage with respect to time convolved with an exponential decay is given by Equation 13:

$$V ( t ) = \frac{1}{T} \int {V}_{i n} ( t - τ ) {e}^{- τ / T} d τ \qquad ( 13 )$$

where T is the RL decay time constant.

Then the magnetic field in the middle center of the deflector coil directly generated by its input voltage, in the absence of electrodynamic effects is given by Equation 14:

$${B}_{0} ( t ) = \frac{μ n V ( t )}{R} \hat{z} = \frac{μ n}{R T} \int {V}_{i n} ( t - τ ) {e}^{- τ / T} d τ \hat{z} \qquad ( 14 )$$

The total magnetic field in the middle-center of each deflector coil will also include contributions from the other three deflector coils. The two other deflector coils oriented perpendicularly will have a small perpendicular contribution—the magnetic field contributions of the two perpendicular deflector coils along the axis will cancel (FIG. 2A). Thus, the total magnetic field in the middle-center of each deflector coil is given by Equation 15:

$${B}_{0}^{′} ( t ) = - {A}_{B} ( \frac{w}{2} \hat{s} + \frac{w}{2} \hat{z} ) ‖ {B}_{0} ( t ) ‖ \hat{s} + ( 1 - {A}_{B} ( w \hat{s} ) ) ‖ {B}_{0} ( t ) ‖ \hat{z} = - {A}_{B} ( \frac{w}{2} \hat{s} + \frac{w}{2} \hat{z} ) \cdot \frac{μ n {V}_{o t h e r} ( t )}{R} \hat{s} + ( 1 - {A}_{B} ( w \hat{s} ) ) \cdot \frac{μ n {V}_{t h i s} ( t )}{R} \hat{z} \qquad ( 15 )$$

where ŝ is the unit vector orthogonal to the axis of the cylindrical deflector coil (FIG. 3), Vₜₕᵢₛ is the voltage applied to this deflector coil, and Vₒₜₕₑᵣ is the voltage applied to the other orthogonal pair of deflector coils.

To improve readability and for convenience, following constants can be defined according to Equations 16a and 16b:

$${A}_{⊥} = \frac{μ n}{R} {A}_{B} ( \frac{w}{2} \hat{s} + \frac{w}{2} \hat{z} ) \qquad ( 16 a )$$

$${A}_{‖} = \frac{μ n}{R} ( 1 - {A}_{B} ( w \hat{s} ) ) \qquad ( 16 b )$$

Therefore, the total magnetic field in the middle-center of each deflector coil is given by Equation 17:

$${B}_{0}^{′} ( t ) = {A}_{‖} {V}_{t h i s} ( t ) \hat{z} - {A}_{⊥} {V}_{o t h e r} ( t ) \hat{s} \qquad ( 17 )$$

Movement of the electron beam by the deflector coils is accomplished by changing the deflector coils' magnetic fields (Equations 8a and 8b) by changing the input voltage for the x and y deflector coils.

The change in the magnetic field in the middle-center of each deflector coil with respect to time is given by Equation 18:

$$\frac{\partial {B}_{0}^{′} ( t )}{\partial t} = {A}_{‖} \frac{d {V}_{t h i s} ( t )}{d t} \hat{z} - {A}_{⊥} \frac{d {V}_{o t h e r} ( t )}{d t} \hat{s} \qquad ( 18 )$$

Faraday's law states that a changing magnetic field induces an electric field according to Equation 19:

$$∇ \times E = - \frac{\partial B}{\partial t} \qquad ( 19 )$$

Separating the two directions in Equation 18 shows that the changing magnetic field induces two electric fields (eddy currents) given by Equations 20a and 20b:

$$∇ \times {E}_{‖} ( t ) = - {A}_{‖} \frac{d {V}_{t h i s} ( t )}{d t} \hat{z} \qquad ( 20 a )$$

$$∇ \times {E}_{⊥} ( t ) = {A}_{⊥} \frac{d {V}_{o t h e r} ( t )}{d t} \hat{y} \qquad ( 20 b )$$

where ŷ is the unit vector orthogonal to the axis of the deflector coil pointing directly away from the point where the electron beam passes through the plane of the deflector.

From Equation 20b, the eddy current induced by the changing voltage of the other pair of deflector coils will exist in a plane that is parallel with the axis of the deflector coil. The geometry of the deflector coil will prevent this current from occurring in the wires around the deflector coil, and therefore this eddy current can only occur within the core of the deflector coil, which has limited electrical conductivity. Additionally, the resulting magnetic field will be parallel with the magnetic field generated by the other pair of deflector coils, which means it is orthogonal to the field generated by this deflector coil and thus can be ignored. Based on this, it is reasonable to conclude that changes in the voltage applied to the other pair of deflector coils do not affect the magnetic field of a given defector coil.

From Equation 20a, the eddy current induced by the changing parallel magnetic field will be circumferential in the opposite direction as the change in current due to the changing input voltage. The current will be greatest within the deflector coil wires, since these are located at the outer circumference of the deflector coil, and they have significantly higher electrical conductivity than the core material. Therefore, the induced current from the parallel magnetic field can be approximated as only occurring within the deflector coil wires.

Integration of Faraday's law yields Equation 21:

$$\int ( ∇ \times E ) \cdot da = ∮ E \cdot dl = - \int \frac{\partial B}{\partial t} \cdot da \qquad ( 21 )$$

Therefore, the changing parallel magnetic field is given by Equation 22:

$$∮ {E}_{‖} ( t ) \cdot dl = 2 π rE ( t ) = - \int {A}_{B} ( a ) \cdot {A}_{‖} \frac{d {V}_{t h i s} ( t )}{d t} \cdot da = - {A}_{‖} \frac{d {V}_{t h i s} ( t )}{d t} \cdot \int {A}_{B} ( a ) \cdot da \qquad ( 22 )$$

Because the magnetic field scaling factor A_{B}(r) depends on the geometry of the deflector coil, which is fixed, its integrated value over the coil's cross section can be assigned as a constant given by Equation 23:

$${A}_{i n t} = \int {A}_{B} ( a ) \cdot da \qquad ( 23 )$$

So that the induced electric field is given by Equations 24a and 24b:

$$2 π r E ( t ) = - {A}_{‖} {A}_{i n t} \frac{d {V}_{this} ( t )}{d t} \qquad ( 24 a )$$

$$E ( t ) = - \frac{{A}_{‖} {A}_{i n t}}{2 π r} \frac{{dV}_{t h i s} ( t )}{dt} \qquad ( 24 b )$$

and therefore the induced current density is given by Equation 25:

$${J}_{‖} ( t ) = σ E ( t ) \hat{ϕ} = - \frac{δ {A}_{‖} {A}_{int}}{2 π r} \frac{{dv}_{this} ( t )}{dt} \hat{ϕ} \qquad ( 25 )$$

where \hat{ϕ} is the unit vector around the circumference of the cylindrical deflector coil, r is the radius of the deflector coil cylinder, and σ is the electrical conductivity of the deflector coil wires.

Similar to the input current, the induced current also persists with an exponential decay given by Equation 26:

$${J}_{∥} ( t ) = - \frac{σ {A}_{∥} {A}_{i n t}}{2 π r} ( \frac{1}{T} \int \frac{d {V}_{this} ( t - τ )}{d t} {e}^{- τ / T} d τ ) \hat{ϕ} \qquad ( 26 )$$

Additionally, the changing voltage applied to the deflector coil also changes its electric field. The electric field in the deflector coil wires is the voltage gradient per unit length as given by Equation 27:

$$E ( t ) = - \frac{1}{2 π r N} {V}_{this} ( t ) \hat{ϕ} \qquad ( 27 )$$

And yielding Equation 28:

$$\frac{\partial E ( t )}{\partial t} = - \frac{1}{2 π r n l} \frac{d {V}_{this} ( t )}{d t} \hat{ϕ} \qquad ( 28 )$$

where l is the total length of the deflector coil.

Therefore, the total magnetic field induced by the changing voltage of the deflector coil is given by Equation 29:

$${B}_{0 , ind} ( t ) = ∮ B ( t ) \cdot d 1 = μ \int J ( t ) \cdot da + μϵ \int \frac{\partial E ( t )}{\partial t} \cdot da = ( - \frac{μ σ n l a {A}_{∥} {A}_{i n t}}{2 π} ( \frac{1}{T} \int \frac{d {V}_{this} ( t - τ )}{d t} {e}^{- τ / T} d τ ) - \frac{μϵ}{2 π rn} \frac{{dV}_{this} ( t )}{dt} ) \hat{z} \qquad ( 29 )$$

where a is the cross-sectional area of the wire in the deflector coil.

Therefore, adding the effects of the changing voltage to Equation 18, considering only the relevant 2 direction, the total magnetic field amplitude in the middle-center of each deflector coil is given by Equation 30:

$$\begin{matrix}{B}_{0 , total}^{′} ( t ) = {B}_{0}^{′} ( t ) + {B}_{0 , ind} ( t ) \\ = {A}_{∥} {V}_{this} ( t ) - \frac{μ σ n l a {A}_{∥} {A}_{i n t}}{2 π} ( \frac{1}{T} \int \frac{d {V}_{this} ( t - τ )}{d t} {e}^{- τ / T} d τ ) - \frac{μϵ}{2 π r n} \frac{d {V}_{this} ( t )}{d t} \\ = {A}_{∥} ( {V}_{this} ( t ) - \frac{μ σ n l a {A}_{i n t}}{2 π} ( \frac{1}{T} \int \frac{d {V}_{this} ( t - τ )}{d t} {e}^{- τ / T} d τ ) - \frac{μϵ}{2 π {rnA}_{∥}} \frac{{dV}_{this} ( t )}{dt} )\end{matrix} \qquad ( 30 )$$

Letting w be the distance between the pairs of deflector coils. The magnetic field experienced by the electron beam due to one pair of parallel deflector coils is given by Equation 31:

$${B}_{e} ( t ) = - 2 \cdot {A}_{field} ( \frac{w}{2} \hat{s} ) \cdot {B}_{0 , total}^{′} ( t ) \cdot \hat{z} \qquad ( 31 )$$

Based on Equation 8, the position of the electron beam is (only the x direction is shown, although the equation for the y direction will be identical) given by Equation 32:

$$\begin{matrix}x ( t ) \approx {A}_{dis} {B}_{y} \\ \approx - 2 \cdot {A}_{d i s} \cdot {A}_{B} ( \frac{w}{2} \hat{s} ) \cdot {B}_{0 , total}^{′} ( t )\end{matrix} \qquad ( 32 )$$

Combining constants for convenience, yields Equation 33:

$$x ( t ) \approx A ( {V}_{this} ( t ) - B ( \frac{1}{T} \int \frac{d {V}_{this} ( t - τ )}{d t} {e}^{- τ / T} d τ ) - C \frac{d {V}_{this} ( t )}{d t} ) \qquad ( 33 )$$

where A is given by Equation 34a, B is given by Equation 34b, and C is given by Equation 34c:

$$\begin{matrix}A = - 2 \cdot {A}_{d i s} \cdot {A}_{B} ( \frac{w}{2} \hat{s} ) \cdot {A}_{∥} \\ = - 2 \cdot \frac{q {d}_{D} {d}_{S}}{ν m} \cdot {A}_{B} ( \frac{w}{2} \hat{s} ) \cdot ( \frac{μ n}{R} ( 1 - {A}_{B} ( w \hat{s} ) ) ) \\ = \frac{- 2 q {d}_{D} {d}_{S} μ n}{R v m} \cdot {A}_{B} ( \frac{w}{2} \hat{s} ) \cdot ( 1 - {A}_{B} ( w \hat{s} ) )\end{matrix} \qquad ( 34 a )$$

$$\begin{matrix}B = \frac{μ σ n l a {A}_{i n t}}{2 π} \\ = \frac{μ σ n l a}{2 π} \int {A}_{B} ( a ) \cdot da\end{matrix} \qquad ( 34 b )$$

$$\begin{matrix}C = \frac{μϵ}{2 π r n {A}_{∥}} \\ = \frac{μϵ}{2 π r n ( \frac{μ n}{R} ( 1 - {A}_{B} ( w \hat{s} ) ) )} \\ = \frac{ϵ R}{2 π r {n}^{2} ( 1 - {A}_{B} ( w \hat{s} ) )}\end{matrix} \qquad ( 34 c )$$

The units of which are given by Equations 35a, 35b, and 35c:

$$A = \frac{( 1 ) ( s \cdot A ) ( m ) ( m ) ( kg \cdot m \cdot {s}^{- 2} \cdot {A}^{- 2} ) ( {m}^{- 1} )}{( kg \cdot {m}^{2} \cdot {s}^{- 3} \cdot {A}^{- 2} ) ( m \cdot {s}^{- 1} ) ( kg )} ( 1 ) ( 1 ) = \frac{{s}^{3} \cdot A}{kg \cdot m} = \frac{m}{V} \qquad ( 35 a )$$

$$B = \frac{( kg \cdot m \cdot {s}^{- 2} \cdot {A}^{- 2} ) ( {kg}^{- 1} \cdot {m}^{- 3} \cdot {s}^{3} \cdot {A}^{2} ) ( {m}^{- 1} ) ( m ) ( {m}^{2} )}{( 1 )} ( 1 ) = s \qquad ( 35 b )$$

$$C = \frac{( {m}^{- 3} \cdot {kg}^{- 1} \cdot {s}^{4} \cdot {A}^{2} ) ( kg \cdot {m}^{2} \cdot {s}^{- 3} \cdot {A}^{- 2} )}{( 1 ) ( m ) {( {m}^{- 1} )}^{2} ( 1 )} = s \qquad ( 35 c )$$

Including the time constant T, there are four parameters that must be determined for each particular. Assuming that the electron beam is aligned in the center of the deflector coils, three of these parameters (B, C, and T) should be constant for each device, since they depend only on the deflector coil geometry and materials. The other parameter, A, additionally depends on the electron accelerating voltage being used.

The first parameter, A, can be determined in the steady state, where the deflector coil voltage is set to a constant value for time t>>T. When V_this (t) is constant, the terms including B, C, and T are zero.

The other three parameters are more challenging to determine, likely requiring trail-and-error techniques to find optimal values. The trial-and-error methods may be optimized to include gradient descent and/or ML to converge on optimal values quickly.

It may be helpful to define the ratio of the two coefficient parameters using Equation 36:

$$\begin{matrix}\frac{B}{C} = ( \frac{μ σ n l a}{2 π} \int {A}_{B} ( a ) \cdot da ) ( \frac{2 π r {n}^{2} ( 1 - {A}_{B} ( w \hat{s} ) )}{ϵ R} ) \\ = \frac{μ σ {n}^{3} l a r}{ϵ R} ( 1 - {A}_{B} ( w \hat{s} ) ) \int {A}_{B} ( a ) \cdot da\end{matrix} \qquad ( 36 )$$

For a magnetic dipole (like a deflector coil), far from the poles, the magnetic field strength falls off as the cube of the distance from the poles. Therefore, A_{B}(wŝ) is expected to be much less than 1 (A_{B}(wŝ)<<1). Additionally, the total magnetic field strength inside the deflector coil (calculated in the integral in Equation 33) can be approximated constant, so that ∫A_{B}(a)·da≈1. Therefore, Equation 36 can be simplified as Equation 37:

$$\frac{B}{C} \approx \frac{μ σ {n}^{3} l a r}{ϵ R} \qquad ( 37 )$$

Although the precise value of each of the components of Equation 34 is not known, their order of magnitude can be estimated as follows: μ˜10⁻¹ H/m, σ˜10⁷ S/m, n˜10⁴ 1/m, l˜10⁻² m, a˜10⁻⁷ m², r˜10⁻² m, ϵ˜10⁻¹⁰ F/m, and R˜10⁻²Ω.

Therefore the magnitude of ratio B/C can be given by Equation 38:

$$\frac{B}{C} ∼ \frac{( 1 {0}^{- 1} H \cdot {m}^{- 1} ) ( 1 {0}^{7} S \cdot {m}^{- 1} ) {( 1 {0}^{4} {m}^{- 1} )}^{3} ( 1 {0}^{- 2} m ) ( 1 {0}^{- 7} {m}^{2} ) ( 1 {0}^{- 2} m )}{( 1 {0}^{- 10} F \cdot {m}^{- 1} ) ( 1 {0}^{- 2} Ω )} ∼ \frac{\begin{matrix}( {10}^{- 1} kg \cdot m \cdot {s}^{- 2} \cdot {A}^{- 2} ) ( 1 {0}^{7} {kg}^{- 1} \cdot {m}^{- 3} \cdot {s}^{3} \cdot {A}^{2} ) \\ {( {10}^{4} {m}^{- 1} )}^{3} ( 1 {0}^{- 2} m ) ( 1 {0}^{- 7} {m}^{2} ) ( 1 {0}^{- 2} m )\end{matrix}}{( {10}^{- 10} \cdot {kg}^{- 1} \cdot {m}^{- 3} \cdot {s}^{4} \cdot {A}^{2} ) ( 1 {0}^{- 2} kg \cdot {m}^{2} \cdot {s}^{- 3} \cdot {A}^{- 2} )} ∼ {10}^{19} \qquad ( 38 )$$

Since B>>C, the term with C may be ignored so that the final model is given by Equation 39:

$$x ( t ) \approx A ( {V}_{this} ( t ) - B ( \frac{1}{T} \int \frac{d {V}_{this} ( t - τ )}{d t} {e}^{- τ / T} d τ ) ) \qquad ( 39 )$$

As discussed above, the first parameter, A, can be easily calibrated at the device.

The order of magnitude of the other two parameters, B and C, can be estimated based on the order of magnitude estimates of the parameters used in Equation 38. The order of magnitude of the parameter B can be estimated by plugging in the corresponding estimated values into Equation 34b. The order of magnitude of the parameter T can be estimated based on the estimated LR time constant for a copper wire with similar diameter and length. Therefore, an estimate is given by Equations 40a and 40b:

$$B ∼ \frac{\begin{matrix}( {10}^{- 1} H \cdot {m}^{- 1} ) ( 1 {0}^{7} {kg}^{- 1} \cdot {m}^{- 3} \cdot {s}^{3} \cdot {A}^{2} ) \\ ( {10}^{4} {m}^{- 1} ) ( 1 {0}^{- 2} m ) ( 1 {0}^{- 7} {m}^{2} )\end{matrix}}{( 2 π )} ( 1 ) ∼ 1 s \qquad ( 40 a )$$

$$T ∼ {10}^{- 4} s \qquad ( 40 b )$$

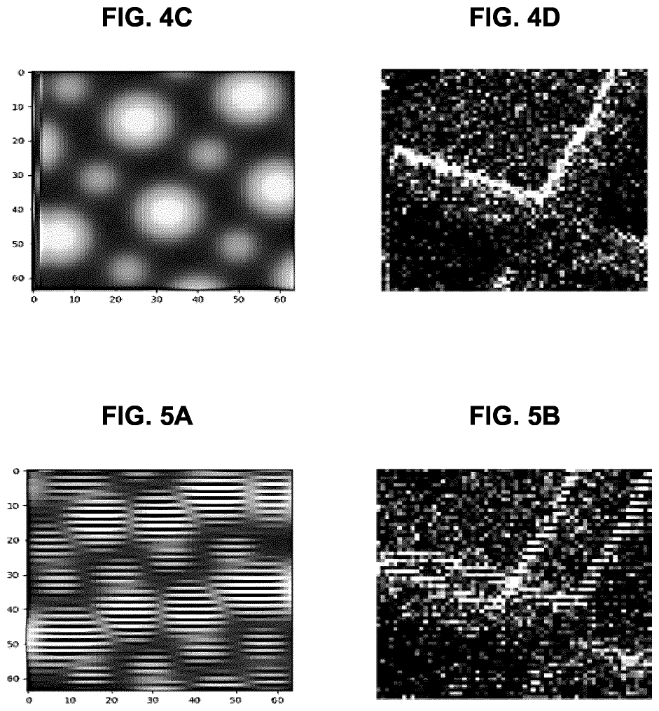

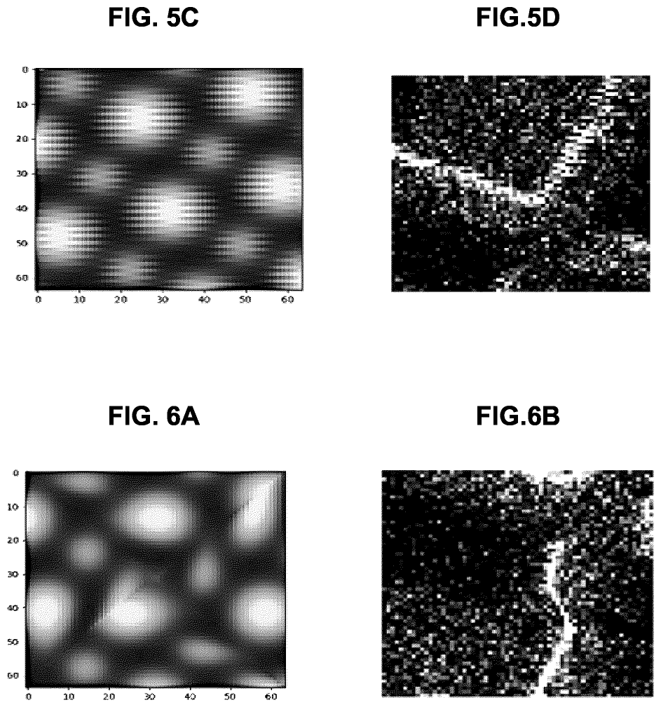

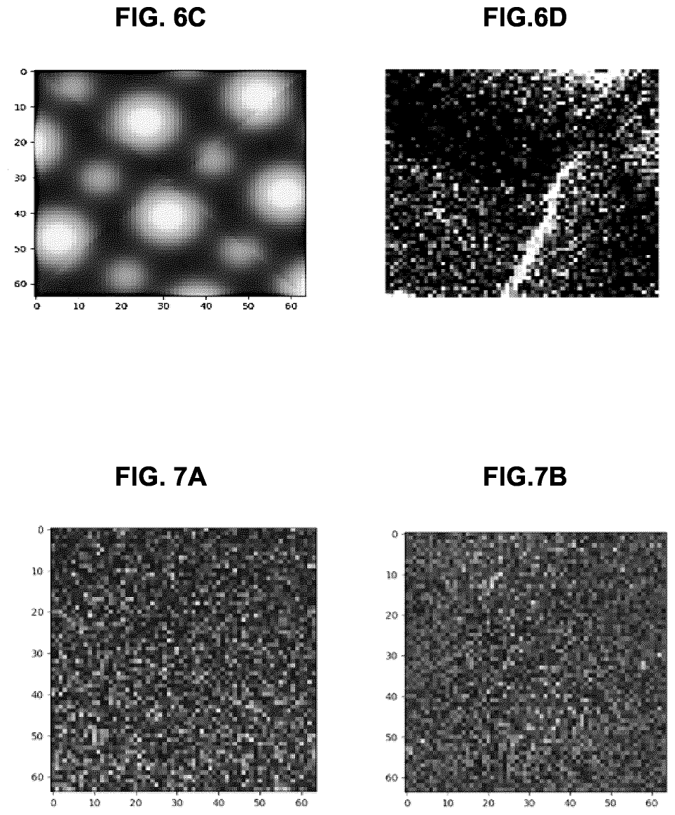

Comparison of simulated data distorted according to Equation 39 shows similar distortion features. Raster scan patterns show artifacts on the left edge of each row (FIGS. 4A-4D), serpentine scan patterns show even and odd rows shifted in the X direction relative to each other (FIGS. 5A-5D), and rectangular spiral scan patterns show a distortion along an X centered on the image (FIGS. 6A-6D). Additionally, these distortions are significantly larger for short dwell times (e.g., 10 μs) compared to longer dwell times (e.g., 100 μs). The effect of these scan distortions render random scan patterns impractical for all but very long dwell times.

The above model was used to calculate distortion corrections using an iterative approach. For each desired scan point, the input voltages for the x and y scan coils were estimated assuming no distortions. Then, the theoretical model described above was used to calculate the actual position of the beam, given the recent history of the beam's position and the input voltages. The deviation between the desired and actual beam position was calculated, and the x and y voltages were adjusted to move the beam closer to the target position. This process is repeated iteratively until the calculated actual position of the beam is within a pre-determined margin-of-error of the target position.

As pseudocode, the iterative method can be described as follows:

```
For each targetCoordinate in scanPattern:
  coilInputVoltages = ConvertCoordinateToVoltage(targetCoordinate)
  loop:
    actualCoordinate = CalculateCoordinateWithDistortion(
      coilInputVoltages, historyOfPreviousVoltages)
    error = targetCoordinate − actualCoordinate
    if abs(error) < errorThreshold:
      exit loop
    coilInputVoltages += ConvertCoordinateToVoltage(error)
  send coilInputVoltages to scan coil hardware
```

The CalculateCoordinateWithDistortion function applied the model of scan coil behavior (Equation 39) to calculate the actual coordinate position of the electron beam from the voltages to be sent to the electromagnetic coils and the history of previous voltages that already have been sent to the electromagnetic coils.

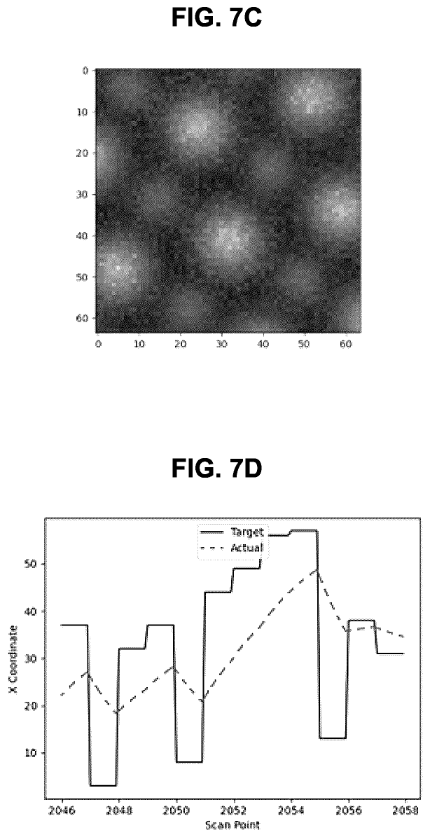

To evaluate the ability to correct scan distortions through iterative correction, STEM scans were simulated with a variety of scan patterns, with and without distortion correction. Distortion correction was applied by iteratively adjusting the output X and Y output voltages until the calculated position best matched the target position for each point on the scan pattern. To include dynamic effects of the changing magnetic field in the scan coil over time, the specimen intensity was integrated across the moving position of the beam at 10× the time resolution compared to the dwell time. The results are shown in FIGS. 7A-7C. These figures show simulated HAADF STEM images of SrTiO₃ with 0.1 Å/pixel with 64×64 pixels and a dwell time of 10 μs, 100 μs, 1000 μs. The voltage range of the scan coil was-0.5 to 0.5 volts. The scan distortion parameters were B=2 s and T=80 μs. The lagging nature of the scan coil response means that rapid movements from one position to another are not possible—the electron beam never gets to the desired position before it is moved again (FIG. 7D). FIG. 7D is a plot showing the x coordinate for 12 scan points near the middle of the 10 μs dwell time simulation shown in FIG. 7A. The desired x coordinate on the specimen is shown in the solid line, while the actual x coordinate of the beam due to the behavior of the scan coils is shown using the dashed line. Consequently, the data acquired with a random scan pattern and a short dwell time is meaningless. Only by using long dwell times (e.g., >1000 μs dwell time) does each point have sufficient time to settle to the desired value. Even so, because some scan points preceded by large beam movements have larger distortions, and the beam is moving during each long dwell time, the contrast is noticeably worse compared to a conventional scan pattern.

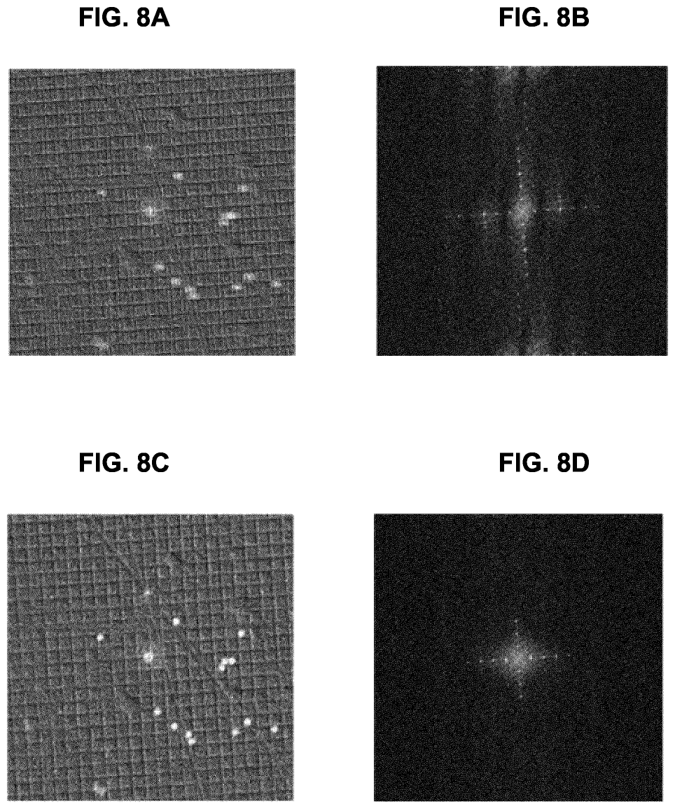

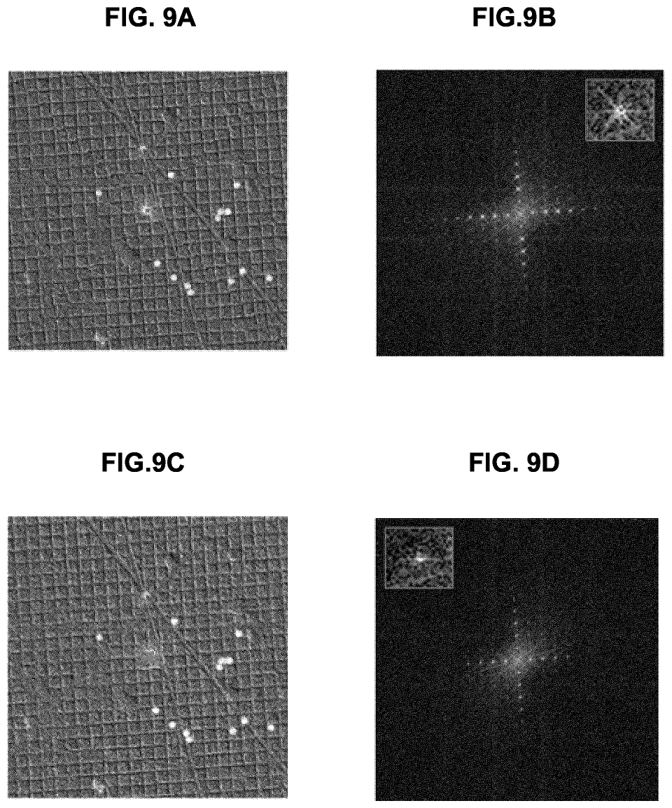

Results of correction applied to real samples is shown in FIGS. 8A-8D for a serpentine scan pattern and FIGS. 9A-9D for a rectangular spiral scan pattern.

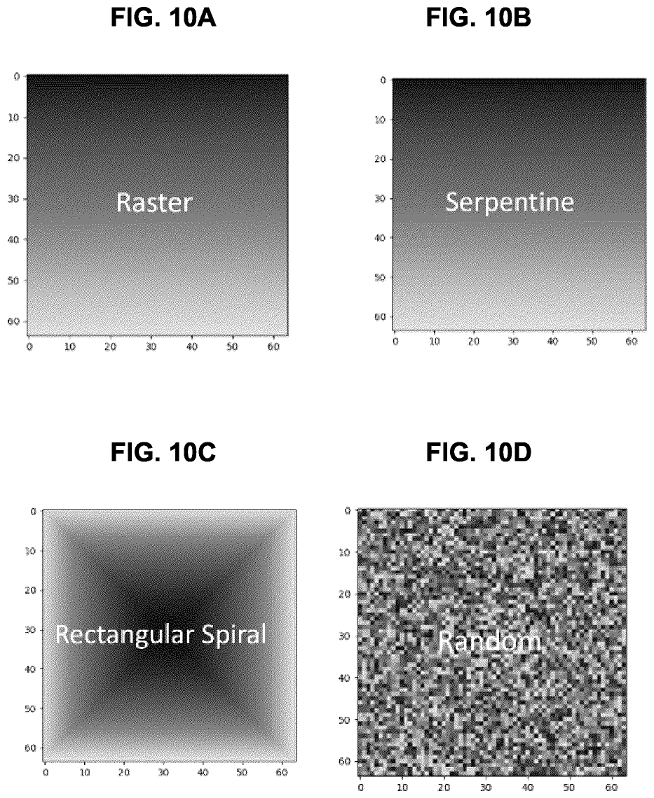

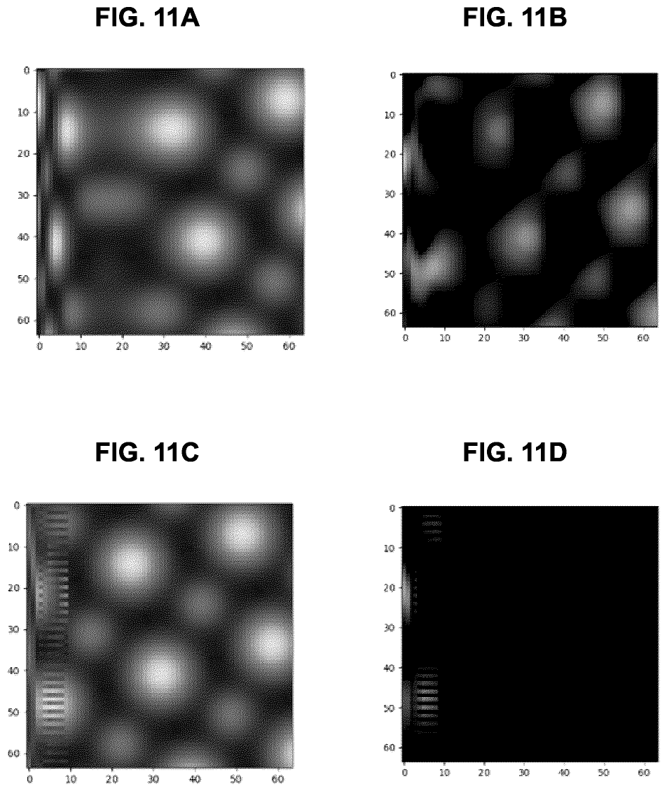

The simulated scan patterns are shown in FIGS. 10A-10D. Simulated results are shown in FIGS. 11A-11D, 12A-12D, 13A-13D, and 14A-14D.

The raster scan (FIGS. 11A-11D) was shifted about 8 pixels to the right in the conventional raster scan, so that the acquired scan area is slightly offset from the desired scan area. This offset was due to the lagging response of the X scan coil after each flyback to the beginning of the next row. Distortion correction eliminated this offset, but it did not completely eliminate the distortions at the beginning of each row. The large change in X voltage to flyback to the beginning of each row could not be immediately compensated by modulating the scan coil voltage. Nevertheless, distortion correction reduced the flyback time delay necessary for conventional raster scans by about 2.2×.

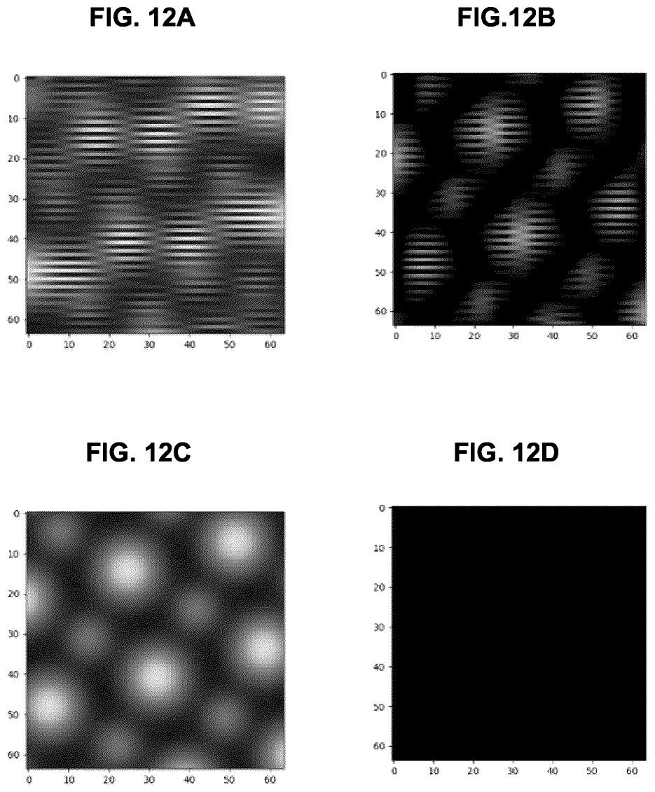

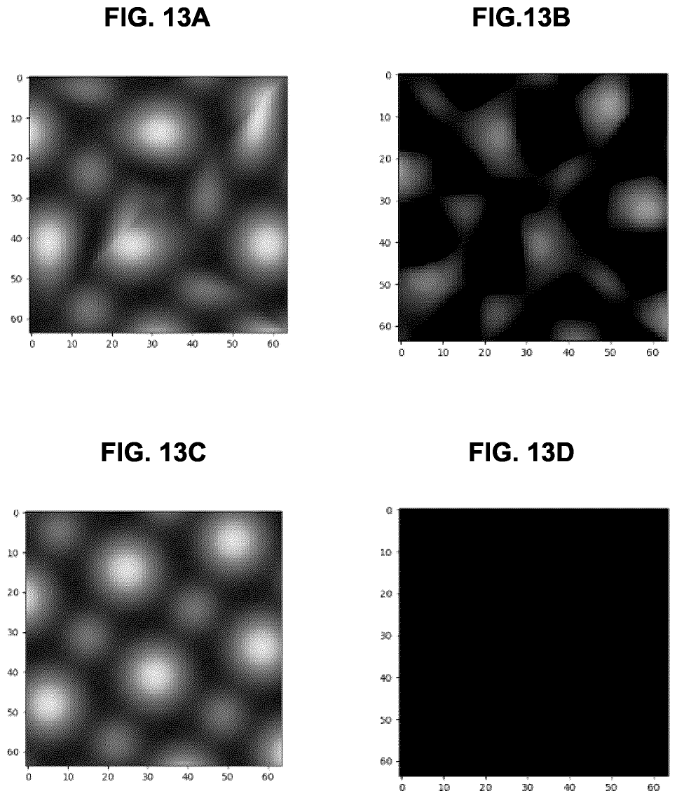

The distortions in serpentine (FIGS. 12A-12D) and rectangular spiral (FIGS. 13A-13D) scans were completely eliminated by distortion correction. Therefore, these scan patterns were considered optimal when distortion correction was enabled-no delays are necessary and distortions are negligible. These scan patterns seem to work well with distortion correction because the change in probe position between consecutive scan points is always only 1 pixel. Distortion correction can address distortions caused by changes in direction of the beam, but distortion correction works best for relatively small changes in position.

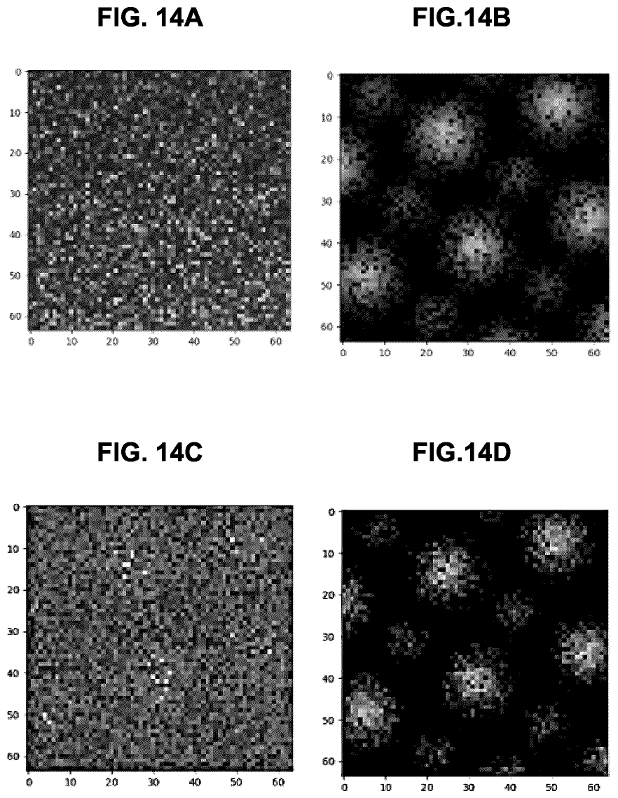

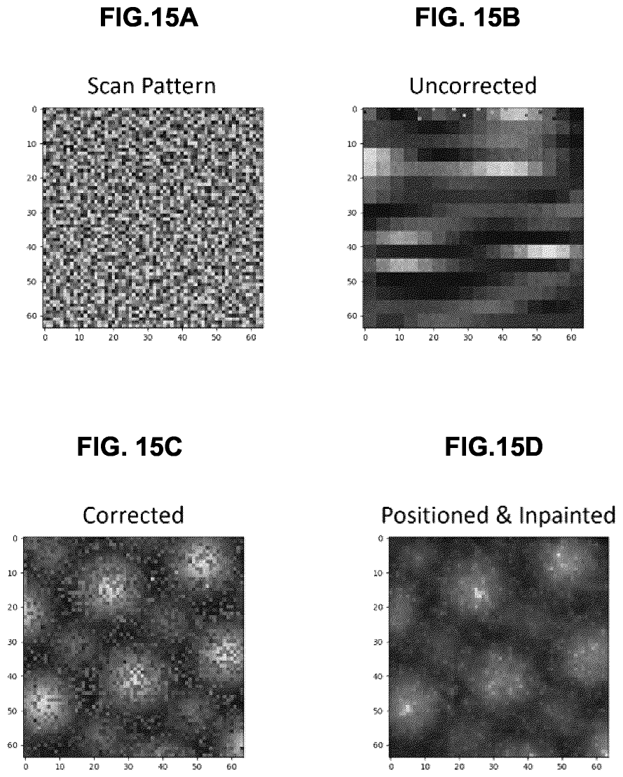

The random scan pattern (FIGS. 14A-14D) yielded meaningless images without distortion correction. When distortion correction was enabled, the high-intensity strontium atoms are barely visible. Clearly distortion correction improves contrast, but random scan patterns are still not practical for short dwell times. Because the random scan pattern frequently involves very large changes in position of the probe, the scan distortions are large and dynamic. Even if the voltage range accepted by the scan coils were large enough to force the beam to the correct average position during the dwell time of each point, the changing magnetic field in the scan coil during the dwell time means that each image pixel is actually integrated over a range of specimen positions. It may be possible to address these challenges by dynamically changing the voltage during the dwell time of each scan point, or by using an ultra-fast beam blanker to only expose the specimen to the beam for a fraction of the dwell time.

The iterative method of distortion correction was implemented in a Direct Electron FreeScan scan generator, so that it adjusted the voltages output from the scan generator to the scan coils for each scan point in the desired scan pattern to minimize distortions predicted by the physics-based distortion model. Therefore, the horizontal and vertical voltages applied to the scan coils were the values necessary to position the electron beam at the desired position. Results show a striking reduction in scan distortion for unconventional scan patterns, such as serpentine (FIGS. 8A-8D) or rectangular spiral (FIGS. 9A-9D) patterns. Notably, no flyback or other delays have been introduced and no post-processing were required.

FIGS. 8A-8D and 9A-9D show 2D STEM (HAADF) images of a line-grating calibration specimen, acquired on a Thermo Fisher Scientific Titan Halo STEM at 300 kV, using a DE FreeScan scan generator with and without our new hardware distortion correction enabled. The scan size was 512×512 pixels, with 2.625 μs dwell time. Using a serpentine scan pattern, the uncorrected image (FIG. 8A) shows two interlaced images shifted horizontally with respect to one another. This distortion yields vertical bands and aliasing artifacts in the Fourier transform (FIG. 8B). Enabling distortion correction (FIG. 8C) eliminated these artifacts in both the real-space image and its Fourier transform (FIG. 8D). Using a rectangular spiral scan, the uncorrected image (FIG. 9A) shows a subtle X-shaped distortion where the scan pattern changes direction. This distortion is evident in the X-shaped of peaks in the Fourier transform (FIG. 9B). The corrected image (FIG. 9C) shows no visible distortions or artifacts.

Based on these results, distortion-corrected STEM may be advantageous for increasing the accuracy and speed of STEM experiments, and also enabling a wide range of new scan patterns that were previously impractical due to scan distortions.

1. A charged particle beam device, comprising:
a charged particle source configured to produce a beam of charged particles;
a beam director configured to direct the beam of charged particles to a target; and
processing circuitry configured to
receive a beam desired ending position,
receive a beam starting position,
calculate a director signal based on the beam starting position and the beam desired ending position,
calculate a corrected signal based on the beam starting position, the director signal, a distortion model, and the beam desired ending position, and
transmit an instruction including the corrected signal to the beam director,
wherein the corrected signal causes the beam director to move the beam of charged particles from the beam starting position to a beam corrected ending position.

2. The charged particle beam device according to claim 1, wherein the charged particles are electrons.

3. The charged particle beam device according to claim 1,
wherein the processing circuitry is further configured to receive a beam position history, and
wherein the corrected signal is calculated based on the beam starting position, the director signal, the distortion model, the beam desired ending position, and the beam position history.

4. The charged particle beam device according to claim 1, wherein the processing circuitry is configured to calculate a plurality of corrected signals, each corresponding to a preselected beam desired ending position and the instruction includes the plurality of corrected signals.

5. The charged particle beam device according to claim 4, wherein the plurality of corrected signals is an ordered list where each beam starting position corresponds to an immediately preceding beam desired ending position.

6. The charged particle beam device according to claim 1, further comprising:
a beam position detector,
wherein the beam starting position is received from the beam position detector.

7. The charged particle beam device according to claim 6, wherein the processing circuitry is configured to transmit the instruction including the corrected signal to the beam director prior to receiving a subsequent beam position.

8. The charged particle beam device according to claim 1, wherein the processing circuitry is configured to calculate at least one parameter selected from the group consisting of the director signal and the corrected signal using a machine learning model.

9. The charged particle beam device according to claim 8, wherein the machine learning model is trained using a training set that includes a plurality of director signals and a plurality of beam positions.

10. The charged particle beam device according to claim 1,
wherein the processing circuitry is further configured to calculate a beam uncorrected ending position based on the beam starting position, the director signal, and a distortion model, and
wherein the corrected signal is calculated based on the beam starting position, the director signal, a distortion model, the beam desired ending position, and the beam uncorrected ending position.

11. A method of directing a beam of charged particles, the method comprising:
passing the beam of charged particles through a beam director;
receiving a beam desired ending position;
receiving a beam starting position;
calculating a director signal based on the beam starting position and the beam desired ending position;
calculating a corrected signal based on the beam starting position, the director signal, a distortion model, and the beam desired ending position; and
transmitting an instruction including the corrected signal to the beam director,
wherein the corrected signal causes the beam director to move the beam of charged particles from the beam starting position to a beam corrected ending position.

12. The method according to claim 11, wherein the charged particles are electrons.

13. The method according to claim 11, further comprising:
receiving a beam position history,
wherein the corrected signal is calculated based on the beam starting position, the director signal, the distortion model, the beam desired ending position, and the beam position history.

14. The method according to claim 11, further comprising:
calculating a plurality of corrected signals, each corresponding to a preselected beam desired ending position and the instruction includes the plurality of corrected signals.

15. The method according to claim 14, wherein the plurality of corrected signals is an ordered list where each beam starting position corresponds to an immediately preceding beam desired ending position.

16. The method according to claim 11, wherein the beam starting position is received from a beam position detector.

17. The method according to claim 16, wherein the transmitting the instruction including the corrected signal to the beam director is performed before receiving a subsequent beam position.

18. The method according to claim 11, wherein at least one parameter selected from the group consisting of the director signal and the corrected signal is calculated using a machine learning model.

19. The method according to claim 18, wherein the machine learning model is trained using a training set that includes a plurality of director signals and a plurality of beam positions.

20. The method according to claim 11, further comprising:
calculating a beam uncorrected ending position based on the beam starting position, the director signal, and a distortion model,
wherein the corrected signal is calculated based on the beam starting position, the director signal, a distortion model, the beam desired ending position, and the beam uncorrected ending position.

21. A non-transitory computer-readable medium having stored thereon, computer executable instructions, which when executed by a computer, cause the computer to execute operations, the operations comprising:
receiving a beam desired ending position;
receiving a beam starting position;
calculating a director signal based on the beam starting position and the beam desired ending position;
calculating a corrected signal based on the beam starting position, the director signal, a distortion model, and the beam desired ending position; and
transmitting an instruction including the corrected signal to a beam director,
wherein the corrected signal causes the beam director to move a beam of charged particles passing therethrough from the beam starting position to a beam corrected ending position.

22. The non-transitory computer-readable medium according to claim 21, wherein the charged particles are electrons.

23. The non-transitory computer-readable medium according to claim 21,
wherein the operations further comprise receiving a beam position history, and
wherein the corrected signal is calculated based on the beam starting position, the director signal, the distortion model, the beam desired ending position, and the beam position history.

24. The non-transitory computer-readable medium according to claim 21, wherein the operations further comprise calculating a plurality of corrected signals, each corresponding to a preselected beam desired ending position and the instruction includes the plurality of corrected signals.

25. The non-transitory computer-readable medium according to claim 24, wherein the plurality of corrected signals is an ordered list where each beam starting position corresponds to an immediately preceding beam desired ending position.

26. The non-transitory computer-readable medium according to claim 21, wherein the beam starting position is received from a beam position detector.

27. The non-transitory computer-readable medium according to claim 26, wherein the transmitting the instruction including the corrected signal to the beam director is performed before receiving a subsequent beam position.

28. The non-transitory computer-readable medium according to claim 21, wherein at least one parameter selected from the group consisting of the director signal and the corrected signal is calculated using a machine learning model.

29. The non-transitory computer-readable medium according to claim 28, wherein the machine learning model is trained using a training set that includes a plurality of director signals and a plurality of beam positions.

30. The non-transitory computer-readable medium according to claim 21,
wherein the operations further comprise calculating a beam uncorrected ending position based on the beam starting position, the director signal, and a distortion model, and
wherein the corrected signal is calculated based on the beam starting position, the director signal, a distortion model, the beam desired ending position, and the beam uncorrected ending position.
